(19) United States
(12) Patent Application Publication
(10) Pub. No.: US 2023/0070275 A1
(43) Pub. Date: Mar. 9, 2023

(54) PACKAGE COMPRISING A SUBSTRATE WITH A PAD INTERCONNECT COMPRISING A PROTRUSION

(71) Applicant: QUALCOMM Incorporated, San Diego, CA (US)

(72) Inventors: Anirudh BHAT, San Diego, CA (US); Yuling NIU, San Diego, CA (US); Jay Scott SALMON, San Diego, CA (US)

(21) Appl. No.: 17/470,924

(22) Filed: Sep. 9, 2021

(51) Int. Cl. H01L 23/00; H01L 23/31; H01L 23/495; H01L 23/522; H01L 23/528; H01L 23/532

(52) U.S. Cl. CPC H01L 24/17; H01L 23/3107; H01L 23/4952; H01L 23/5226; H01L 23/5283; H01L 23/53295; H01L 24/81; H01L 2224/17104; H01L 2224/81191

(57) ABSTRACT

A package that includes a substrate and an integrated device coupled to the substrate. The substrate includes at least one dielectric layer and a plurality of interconnects comprising a first pad interconnect. The first pad interconnect comprises a first portion comprising a first width and a second portion comprising a second width that is different than the first width.

### FIELD

Various features relate to packages with a substrate.

### BACKGROUND

A package may include a substrate and integrated devices. These components are coupled together to provide a package that may perform various electrical functions. Cracks at joints of a package may affect the performance of a package. There is an ongoing need to provide better performing packages.

### SUMMARY

Various features relate to packages with a substrate.

One example provides a package that includes a substrate and an integrated device coupled to the substrate. The substrate includes at least one dielectric layer and a plurality of interconnects comprising a first pad interconnect. The first pad interconnect comprises a first portion comprising a first width and a second portion comprising a second width that is different than the first width.

Another example provides an apparatus that includes a substrate. The substrate includes at least one dielectric layer and a plurality of interconnects comprising a first pad interconnect. The first pad interconnect comprises a first portion comprising a first width and a second portion comprising a second width that is different than the first width.

Another example provides a method for fabricating a substrate. The method provides at least one dielectric layer. The method forms a plurality of interconnects comprising a first pad interconnect. The first pad interconnect comprises a first portion comprising a first width and a second portion comprising a second width that is different than the first width.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross-sectional profile view of a package that includes a substrate with a pad interconnect comprising a protrusion.

FIG. 2 illustrates an exemplary close-up view of a package that includes a substrate with a pad interconnect comprising a protrusion.

FIG. 3 illustrates an exemplary cross-sectional profile view of a package that includes a substrate with a pad interconnect comprising a protrusion.

FIG. 4 illustrates an exemplary close-up view of a package that includes a substrate with a pad interconnect comprising a protrusion.

FIG. 5 illustrates an exemplary view of a pad interconnect comprising a protrusion.

FIG. 6 illustrates an example of a crack between a solder and a pad interconnect.

FIG. 7 illustrates an example of a crack between a solder and a pad interconnect comprising a protrusion.

FIG. 8 illustrates exemplary profile views and planar views of pad interconnects comprising protrusions with different shapes.

FIGS. 9A-9D illustrate an exemplary sequence for fabricating a substrate with a pad interconnect comprising a protrusion.

FIG. 10 illustrates an exemplary flow chart of a method for fabricating a substrate with a pad interconnect comprising a protrusion.

FIGS. 11A-11E illustrate an exemplary sequence for fabricating a substrate with a pad interconnect comprising a protrusion.

FIG. 12 illustrates an exemplary flow chart of a method for fabricating a substrate with a pad interconnect comprising a protrusion.

FIGS. 13A-13B illustrate an exemplary sequence for fabricating a package comprising a substrate with a pad interconnect comprising a protrusion.

FIGS. 14A-14B illustrate an exemplary sequence for fabricating a package comprising a substrate with a pad interconnect comprising a protrusion.

FIG. 15 illustrates an exemplary flow chart of a method for fabricating a package comprising a substrate with a pad interconnect comprising a protrusion.

FIG. 16 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package that includes a substrate and an integrated device coupled to the substrate. The substrate includes at least one dielectric layer and a plurality of interconnects comprising a first pad interconnect. The first pad interconnect comprises a first portion comprising a first width and a second portion comprising a second width that is different than the first width. The first width may be greater than the second width. The second width may be less than the first width. The first portion may be a base of the first pad interconnect and the second portion may be a protrusion of the first pad interconnect. The second portion helps prevent the propagation of cracks that may exist between the first pad interconnect and a solder interconnect. Reducing the presence of cracks in joints helps provide improved signals and may help provide improved performances in the integrated device and/or the package.

Exemplary Package Comprising a Substrate with a Pad Interconnect Comprising a Protrusion

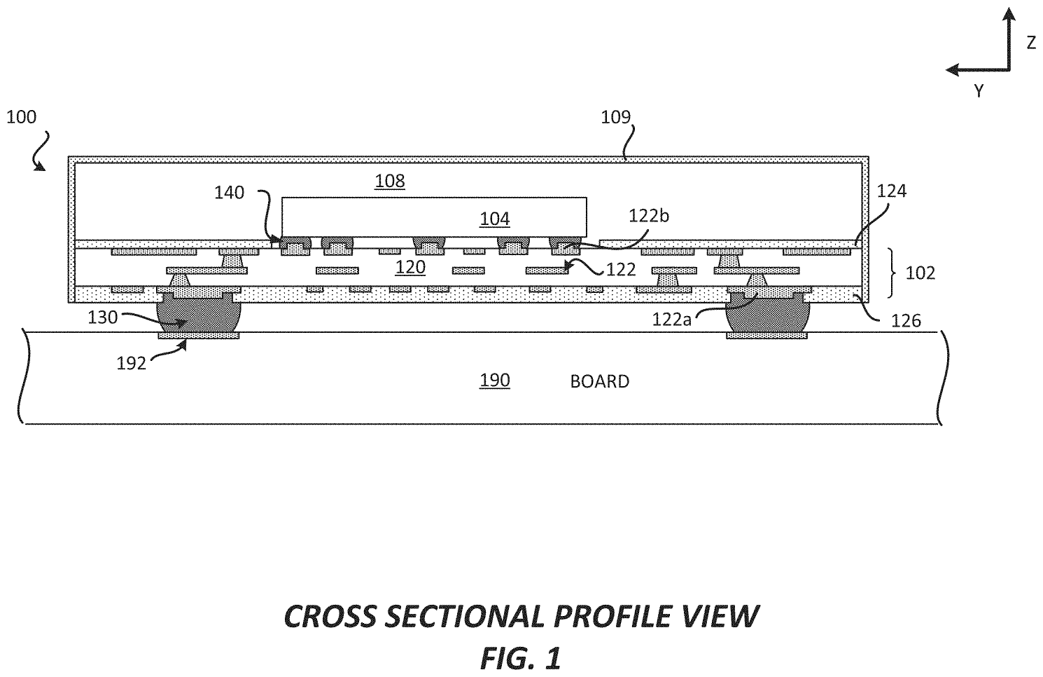

FIG. 1 illustrates a cross-sectional profile view of a package 100 that includes a substrate with a pad interconnect comprising a protrusion. The package 100 includes a substrate 102, an integrated device 104, an encapsulation layer 108, and a metal layer 109. The metal layer 109 is configured as a shield (e.g., electromagnetic interference (EMI) shield). The package 100 is coupled to a board 190 (e.g., printed circuit board) through a plurality of solder interconnects 130. The board 190 includes a plurality of board interconnects 192. The package 100 is coupled to the plurality of board interconnects 192 through the plurality of solder interconnects 130.

The substrate 102 includes at least one dielectric layer 120, a plurality of interconnects 122, a solder resist layer 124, and a solder resist layer 126. The substrate 102 may be a coreless substrate (e.g., embedded trace substrate (ETS)). The substrate 102 may include a first surface (e.g., top surface) and a second surface (e.g., bottom surface). The solder resist layer 124 may be located over the first surface of the substrate 102. The solder resist layer 126 may be located over the second surface of the substrate 102. The plurality of interconnects 122 includes a pad interconnect 122a and a pad interconnect 122b. The pad interconnect 122a may be located over a second surface (e.g., bottom surface) of the substrate 102. The pad interconnect 122b may be located over a first surface (e.g., top surface) of the substrate 102. As will be further described below, the pad interconnect (e.g., 122a, 122b) may include a first portion and a second portion. The first portion may be a base (e.g., base portion) for a pad interconnect, and the second portion may be a protrusion for the pad interconnect. The first portion and/or the second of the pad interconnect help reduce the propagation of cracks that may occur when the integrated device 104 is coupled to the substrate 102 and/or when the package 100 is coupled to a board 190.

The plurality of solder interconnects 130 is coupled to the plurality of interconnects 122 of the substrate 102. A solder interconnect from the plurality of solder interconnects 130 is coupled to the pad interconnect 122a. The integrated device 104 is coupled to a first surface (e.g., top surface) of the substrate 102 through a plurality of solder interconnects 140. For example, the integrated device 104 is coupled to the plurality of interconnects 122 of the substrate 102 through the plurality of solder interconnects 140. A solder interconnect from the plurality of solder interconnects 140 may be coupled to the pad interconnect 122b.

The encapsulation layer 108 is provided (e.g., formed) over the first surface of the substrate 102. The encapsulation layer 108 may encapsulate the integrated device 104. The encapsulation layer 108 may include a mold, a resin and/or an epoxy. A compression molding process, a transfer molding process, or a liquid molding process may be used to form the encapsulation layer 108. The encapsulation layer 108 may be photo etchable. The encapsulation layer 108 may be a means for encapsulation.

The metal layer 109 is located over a surface of the encapsulation layer 108 and the side surface of the substrate 102. The metal layer 109 may be configured as an electromagnetic interference (EMI) shield for the integrated device 104 and/or the package 100. The metal layer 109 may be configured to be coupled to ground. The metal layer 109 may be configured to be coupled to an interconnect from the plurality of interconnects 122.

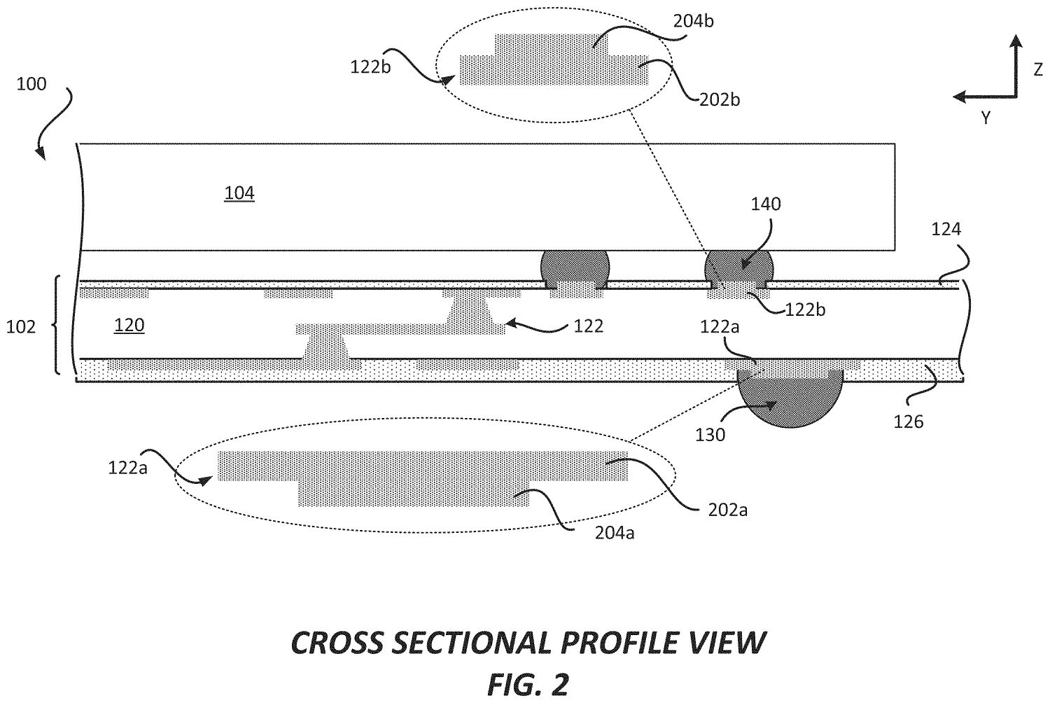

FIG. 2 illustrates an exemplary close-up view of a package. FIG. 2 may illustrate an exemplary representation of the package 100 of FIG. 1. As shown in FIG. 2, the integrated device 104 is coupled to the substrate 102 through the plurality of solder interconnects 140. The substrate 102 includes the at least one dielectric layer 120 and the plurality of interconnects 122. The plurality of interconnects 122 includes the pad interconnect 122a and the pad interconnect 122b.

The pad interconnect 122a is located over a second surface (e.g., bottom surface) of the substrate 102. The pad interconnect 122a includes a first portion 202a and a second portion 204a. The second portion 204a is coupled to the first portion 202a. The first portion 202a has a first width (e.g., first diameter), and the second portion 204a has a second width (e.g., second diameter). The second width is different than the first width. The second width is smaller than the first width. The first portion 202a may be a base of the pad interconnect 122a, and the second portion 204a may be a protrusion of the pad interconnect 122a. The first portion 202a and the second portion 204a are located over a second surface (e.g., bottom surface) of the at least one dielectric layer 120. A solder interconnect from the plurality of solder interconnects 130 is coupled to the pad interconnect 122a. For example, a solder interconnect from the plurality of solder interconnects 130 may be coupled to the first portion 202a and/or the second portion 204a of the pad interconnect 122a. As will be further described below, the second portion 204a increases the surface area that solder may be coupled to, which helps the solder interconnect couple to the pad interconnect 122a. The second portion 204a also creates angles in the joint, which helps stop cracks from propagating in the joint between the solder interconnect and the pad interconnect 122a. This helps provide more robust and reliable joints for signals to travel through in the package. The solder resist layer 126 may be located over part of the first portion 202a of the pad interconnect 122a.

The pad interconnect 122b is located over a first surface (e.g., top surface) of the substrate 102. The pad interconnect 122b includes a first portion 202b and a second portion 204b. The second portion 204b is coupled to the first portion 202b. The first portion 202b has a first width (e.g., first diameter), and the second portion 204b has a second width (e.g., second diameter). The second width is different than the first width. The second width is smaller than the first width. The first portion 202b may be a base of the pad interconnect 122b, and the second portion 204b may be a protrusion of the pad interconnect 122b. The first portion 202b is located in the at least one dielectric layer 120. The second portion 204b is located over a first surface (e.g., top surface) of the at least one dielectric layer 120. A solder interconnect from the plurality of solder interconnects 140 is coupled to the pad interconnect 122b. For example, a solder interconnect from the plurality of solder interconnects 140 may be coupled to the first portion 202b and/or the second portion 204b of the pad interconnect 122b. As will be further described below, the second portion 204b increases the surface area that solder may be coupled to, which helps the solder interconnect reliably couple to the pad interconnect 122b. The second portion 204b also creates angles in the joint, which helps stop cracks from propagating in the joint between the solder interconnect and the pad interconnect 122b. This helps provide a more robust and reliable joints for signals to travel through in the package. The solder resist layer 124 may be located over part of the first portion 202b of the pad interconnect 122b.

The solder resist layer 124 has a thickness that is thicker than the thickness of the second portion 204b of the pad interconnect 122b. The solder resist layer 124 has a thickness that is about the same as the thickness of the second portion 204b of the pad interconnect 122b. The solder resist layer 126 has a thickness that is thicker than the combined thickness of the first portion 202a and the second portion 204a of the pad interconnect 122a. In some implementations, the solder resist layer 126 has a thickness that is about the same as the combined thickness of the first portion 202a and the second portion 204a of the pad interconnect 122a. Having a solder resist layer that has a thickness that is equal or greater than the thickness of a pad interconnect with a protrusion helps ensure a planar surface for the substrate.

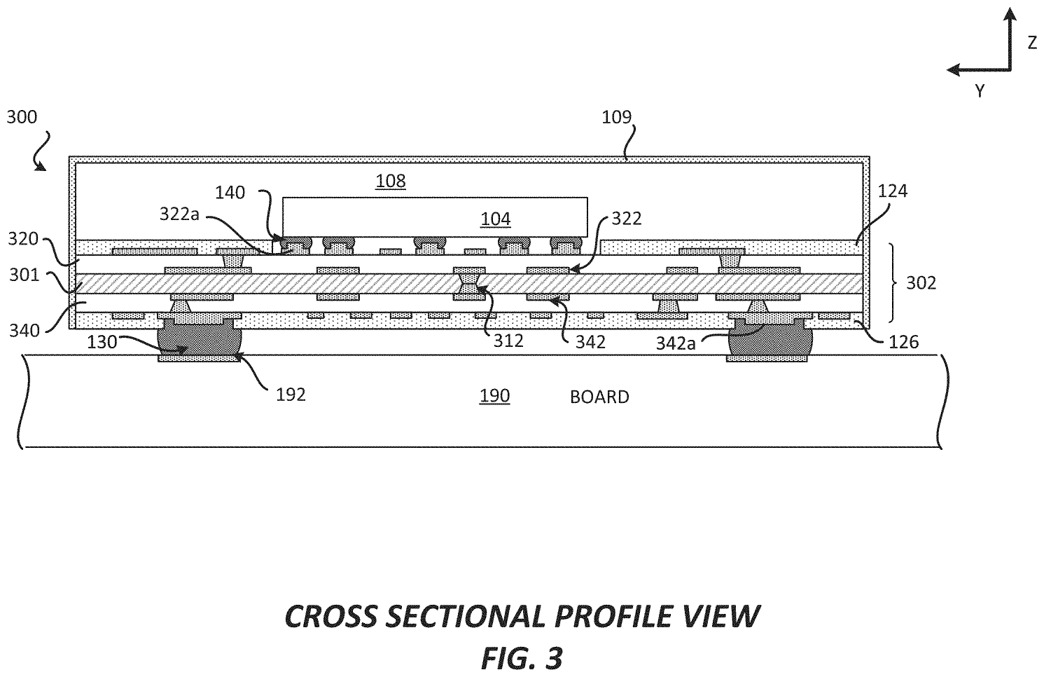

FIG. 3 illustrates a cross-sectional profile view of a package 300 that includes a cored substrate with a pad interconnect comprising a protrusion. The package 300 includes a substrate 302, the integrated device 104, the encapsulation layer 108, and the metal layer 109. The metal layer 109 is configured as a shield (e.g., electromagnetic interference (EMI) shield) for the integrated device 104 and/or the package 300. The package 300 is coupled to the board 190 through a plurality of solder interconnects 130. The board 190 includes a plurality of board interconnects 192. The package 300 is coupled to the plurality of board interconnects 192 through the plurality of solder interconnects 130.

The substrate 302 may be a cored substrate. The substrate 302 includes a core layer 301, at least one dielectric layer 320, at least one dielectric layer 340, a plurality of core interconnects 312, a plurality of interconnects 322, a plurality of interconnects 342, a solder resist layer 124, and a solder resist layer 126. The substrate 302 may include a first surface (e.g., top surface) and a second surface (e.g., bottom surface). The solder resist layer 124 may be located over the first surface of the substrate 302. The solder resist layer 126 may be located over the second surface of the substrate 302. The plurality of interconnects 322 includes a pad interconnect 322a. The plurality of interconnects 342 includes a pad interconnect 342a. As will be further described below, the pad interconnect (e.g., 322a, 342a) may include a first portion and a second portion (e.g., protrusion).

The plurality of solder interconnects 130 is coupled to the plurality of interconnects 342 of the substrate 302. For example, a solder interconnect from the plurality of solder interconnects 130 may be coupled to the pad interconnect 342a. The integrated device 104 is coupled to a first surface (e.g., top surface) of the substrate 302 through a plurality of solder interconnects 140. For example, the integrated device 104 is coupled to the plurality of interconnects 322 of the substrate 302 through the plurality of solder interconnects 140. A solder interconnect from the plurality of solder interconnects 140 may be coupled to the pad interconnect 322a.

The encapsulation layer 108 is provided (e.g., formed) over the first surface of the substrate 302. The encapsulation layer 108 may encapsulate the integrated device 104. The encapsulation layer 108 may include a mold, a resin and/or an epoxy. A compression molding process, a transfer molding process, or a liquid molding process may be used to form the encapsulation layer 108. The encapsulation layer 108 may be photo etchable. The encapsulation layer 108 may be a means for encapsulation.

The metal layer 109 is located over a surface of the encapsulation layer 108 and the side surface of the substrate 302. The metal layer 109 may be configured as an electromagnetic interference (EMI) shield for the integrated device 104 and/or the package 300. The metal layer 109 may be configured to be coupled to ground. The metal layer 109 may be configured to be coupled to an interconnect from the plurality of interconnects 122.

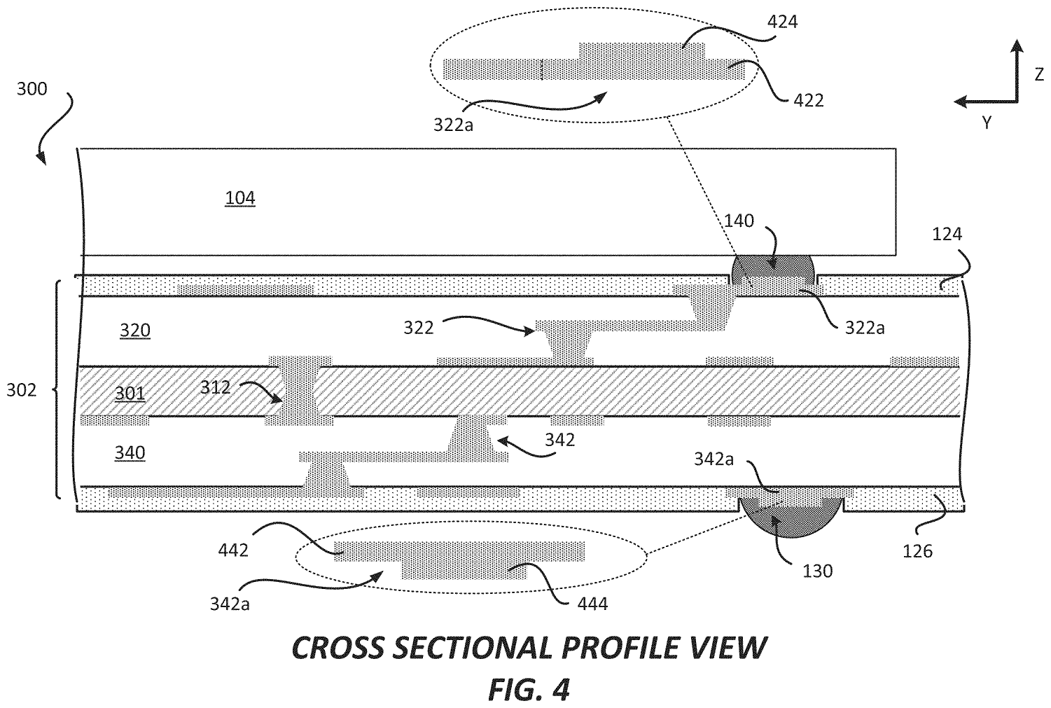

FIG. 4 illustrates an exemplary close-up view of a package. FIG. 4 may illustrate an exemplary representation of the package 300 of FIG. 3. As shown in FIG. 4, the integrated device 104 is coupled to the substrate 302 through the plurality of solder interconnects 140. The substrate 302 includes the core layer 301, the at least one dielectric layer 320, the at least one dielectric layer 340, the plurality of core interconnects 312, the plurality of interconnects 322, and the plurality of interconnects 342. The plurality of interconnects 322 includes the pad interconnect 322a. The plurality of interconnects 342 includes the pad interconnect 342a.

The pad interconnect 322a is located over a first surface (e.g., top surface) of the substrate 302. The pad interconnect 322a includes a first portion 422 and a second portion 424. The first portion 422 and the second portion 424 may be located a surface of the at least one dielectric layer 320. The first portion 422 has a first width (e.g., first diameter), and the second portion 424 has a second width (e.g., second diameter). The second width is different than the first width. The second width is smaller than the first width. The first portion 422 may be a base of the pad interconnect 322a, and the second portion 424 may be a protrusion of the pad interconnect 322a. The first portion 422 and the second portion 424 are located over a first surface (e.g., top surface) of the at least one dielectric layer 320. A solder interconnect from the plurality of solder interconnects 140 is coupled to the pad interconnect 322a. For example, a solder interconnect from the plurality of solder interconnects 140 may be coupled to the first portion 422 and/or the second portion 424 of the pad interconnect 322a. As will be further described below, the second portion 424 increases the surface area that solder may be coupled to, which helps the solder interconnect reliably couple to the pad interconnect 322a. The second portion 424 also creates angles in the joint, which helps stop cracks from propagating in the joint between the solder interconnect and the pad interconnect 322a. This helps provide a more robust and reliable joints for signals to travel through in the package. The solder resist layer 124 may be located over part of the first portion 422 of the pad interconnect 322a.

The pad interconnect 342a is located over a second surface (e.g., bottom surface) of the substrate 302. The pad interconnect 342a includes a first portion 442 and a second portion 444. The first portion 442 and the second portion 444 may be located over a surface of the at least one dielectric layer 340. The first portion 442 has a first width (e.g., first diameter), and the second portion 444 has a second width (e.g., second diameter). The second width is different than the first width. The second width is smaller than the first width. The first portion 442 may be a base of the pad interconnect 342a, and the second portion 444 may be a protrusion of the pad interconnect 342a. The first portion 442 and the second portion 444 are located over a second surface (e.g., bottom surface) of the at least one dielectric layer 340. A solder interconnect from the plurality of solder interconnects 130 is coupled to the pad interconnect 342a. For example, a solder interconnect from the plurality of solder interconnects 130 may be coupled to the first portion 442 and/or the second portion 444 of the pad interconnect 342a. As will be further described below, the second portion 444 increases the surface area that solder may be coupled to, which helps the solder interconnect couple to the pad interconnect 342a. The second portion 444 also creates angles in the joint, which helps prevent cracks from propagating in the joint between the solder interconnect and the pad interconnect 342a. This helps provide more robust and reliable joints for signals to travel through in the package. The solder resist layer 126 may be located over part of the first portion 442 of the pad interconnect 342a.

The solder resist layer 124 has a thickness that is thicker than the combined thickness of the first portion 422 and the second portion 424 of the pad interconnect 322a. In some implementations, the solder resist layer 124 has a thickness that is about the same as the combined thickness of the first portion 422 and the second portion 424 of the pad interconnect 322a. The solder resist layer 126 has a thickness that is thicker than the combined thickness of the first portion 442 and the second portion 444 of the pad interconnect 342a. In some implementations, the solder resist layer 126 has a thickness that is about the same as the combined thickness of the first portion 442 and the second portion 444 of the pad interconnect 342a.

It is noted that pad interconnects with protrusions may be located over one surface (e.g., bottom surface or top surface) of a substrate (e.g., 102, 302) or both surfaces (e.g., bottom surface and top surface) of a substrate (e.g., 102, 302). It is also noted that the pad interconnects described may be implemented in an interposer and/or a board (e.g., printed circuit board).

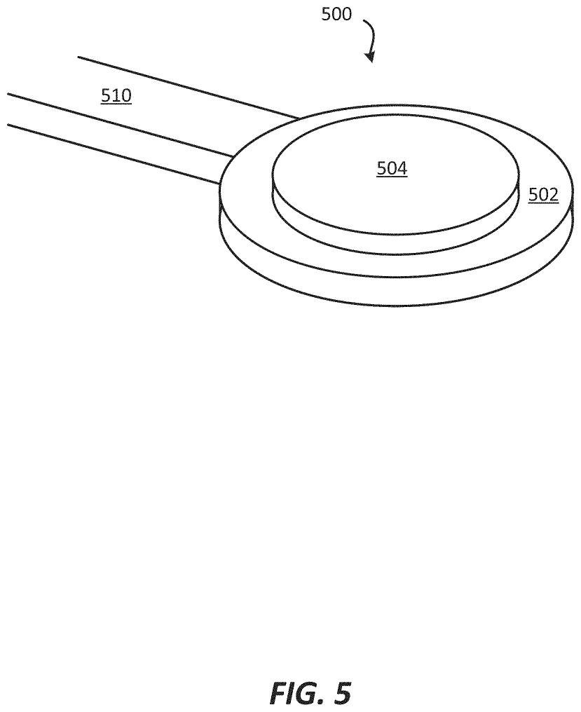

FIG. 5 illustrates an exemplary view of a pad interconnect with a protrusion. FIG. 5 illustrates a pad interconnect 500 coupled to a trace interconnect 510. The pad interconnect 500 may represent any of the pad interconnects with a protrusion described in the disclosure. The trace interconnect 510 may represent any of the trace interconnects described in the disclosure.

The pad interconnect 500 includes a first portion 502 and a second portion 504. The second portion 504 is coupled to the first portion 502. The first portion 502 is coupled to the trace interconnect 510. The first portion 502 has a first width (e.g., first diameter), and the second portion 504 has a second width (e.g., second diameter). The second width is different than the first width. The second width is smaller than the first width. The first portion 502 of the pad interconnect 500 has a planar cross-sectional shape of a first circle (e.g., first circular planar cross-section). The second portion 504 of the pad interconnect 500 has a planar cross-sectional shape of a second circle (e.g., second circular planar cross-section). The second circle has a smaller size than the first circle. The first portion 502 may be a base of the pad interconnect 500, and the second portion 504 may be a protrusion of the pad interconnect 500. The pad interconnect 500 may have the shape of a top hat. The second portion 504 increases the surface area on which solder can couple to. The second portion 504 may also be configured as a crack stop to help stop the propagation of cracks between a solder interconnect and the pad interconnect. The sidewalls of the second portion 504 create a barrier that helps prevent the cracks from propagating through other parts of the pad interconnects. A solder interconnect may be coupled to the first portion 502 and/or the second portion 504 of the pad interconnect 500.

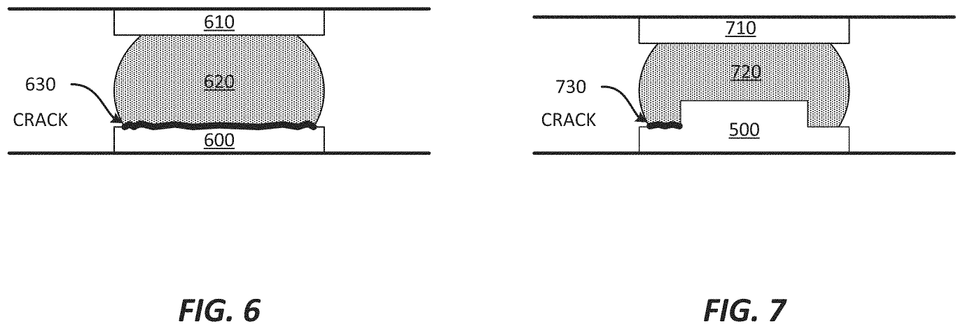

FIGS. 6 and 7 illustrate exemplary views of how crack may be present for different pad interconnects. FIG. 6 illustrate a solder interconnect 620 coupled to a pad interconnect 600 and a pad interconnect 610. The pad interconnect 600 may be a pad interconnect of a substrate. The pad interconnect 610 may be a pad interconnect of an integrated device or a pad interconnect of a board (e.g., printed circuit board). As shown in FIG. 6, there is a crack 630 between the joint of the solder interconnect 620 and the pad interconnect 600. The crack 630 is able to propagate through the entire joint between the solder interconnect 620 and the pad interconnect 600 because the pad interconnect 600 has a relatively flat surface. The crack 630 can cause an open joint or a weak joint, which may result in no signal, weak signals and/or unreliable signals traveling through the pad interconnect 600 and the solder interconnect 620.

FIG. 7 illustrate a solder interconnect 720 coupled to the pad interconnect 500 and a pad interconnect 710. The pad interconnect 500 may be a pad interconnect of a substrate. The pad interconnect 710 may be a pad interconnect of an integrated device or a pad interconnect of a board (e.g., printed circuit board). As shown in FIG. 7, there is a crack 730 between the joint of the solder interconnect 620 and the pad interconnect 500. The crack 730 is smaller than the crack 630 because the protrusion of the pad interconnect 500 helps prevent the crack 730 from propagating any further between the pad interconnect 500 and the solder interconnect 720.

The smaller size of the crack 730 helps provide a stronger and more reliable joint between the pad interconnect 500 and the solder interconnect 720, which may result in improved signals and/or more reliable signals traveling through the pad interconnect 500 and the solder interconnect 720.

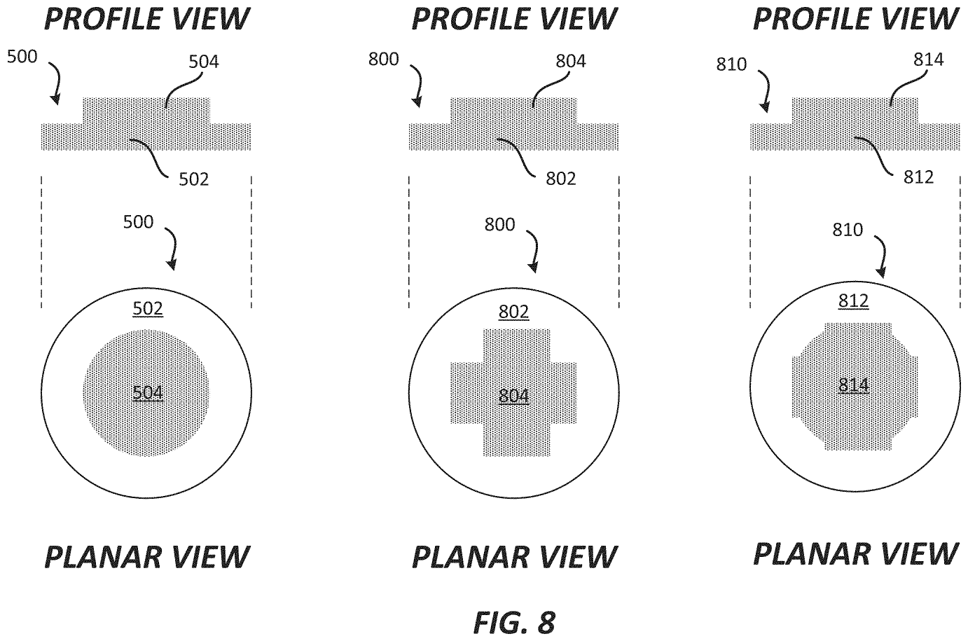

The pad interconnects may have different types of shapes. FIG. 8 illustrate examples of different pad interconnects with protrusion having different shapes. FIG. 8 illustrates the pad interconnect 500, a pad interconnect 800 and a pad interconnect 810.

The pad interconnect 500 includes the first portion 502 and the second portion 504. The second portion 504 is coupled to the first portion 502. The first portion 502 has a planar cross-section in the shape of a circle. The second portion 504 has a planar cross-section in the shape of a circle.

The pad interconnect 800 includes a first portion 802 and a second portion 804. The second portion 804 is coupled to the first portion 802. The first portion 802 has a planar cross-section in the shape of a circle. The second portion 804 has a planar cross-section in the shape of a cross (e.g., cross planar cross-section).

The pad interconnect 810 includes a first portion 812 and a second portion 814. The second portion 814 is coupled to the first portion 812. The first portion 812 has a planar cross-section in the shape of a circle. The second portion 814 has a planar cross-section in the shape of a cross and circle that have been combined (e.g., combined circle and cross).

A solder interconnect may be coupled to the first portion (e.g., 502, 802, 812) and/or the second portion (e.g., 504, 804, 814) of the pad interconnect (e.g., 500, 800, 810). It is noted that the first portion and the second portion of a pad interconnect may have various shapes with various combinations. For example, the first portion and/or the second portion may include a planar cross-section that is circular or non-circular. Non-limiting examples of non-circular planar cross-sections include a triangle, a rectangle, a square, a trapezoid, a polygon, and/or combinations thereof.

It is noted that the first portion and the second portion of a pad interconnect with a protrusion may be considered as one portion, or two or more portions. There may or may not be one or more interfaces between portions of the pad interconnects with a protrusion.

An integrated device (e.g., 104) may include a die (e.g., semiconductor bare die). An integrated device may include integrated circuits. The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filters, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 104) may include at least one electronic circuit (e.g., first electronic circuit, second electronic circuit, etc. . . . ). An integrated device may be an example of an electrical component and/or electrical device.

The package (e.g., 100, 300) may be implemented in a radio frequency (RF) package. The RF package may be a radio frequency front end (RFFE) package. A package (e.g., 100, 300) may be configured to provide Wireless Fidelity (WiFi) communication and/or cellular communication (e.g., 2G, 3G, 4G, 5G). The packages (e.g., 100, 300) may be configured to support Global System for Mobile (GSM) Communications, Universal Mobile Telecommunications System (UMTS), and/or Long-Term Evolution (LTE). The packages (e.g., 100, 300) may be configured to transmit and receive signals having different frequencies and/or communication protocols.

In some implementations, the package (e.g., 100, 300) may include a bottom encapsulation layer that is similar to the encapsulation layer 108. The bottom encapsulation layer may be coupled to a bottom surface of the substrate (e.g., 102, 302). The bottom encapsulation layer may be located over a solder resist layer 126. The bottom encapsulation layer may laterally surround the plurality of solder interconnects 130.

Having described various packages with a substrate, several methods for fabricating a substrate will now be described below.

### Exemplary Sequence for Fabricating a Substrate

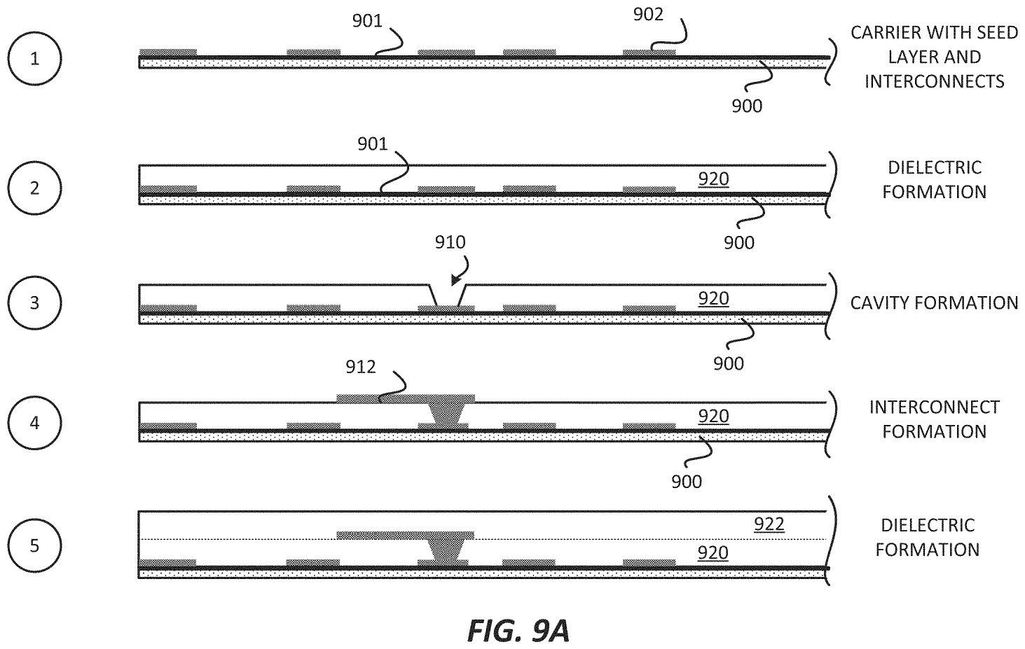

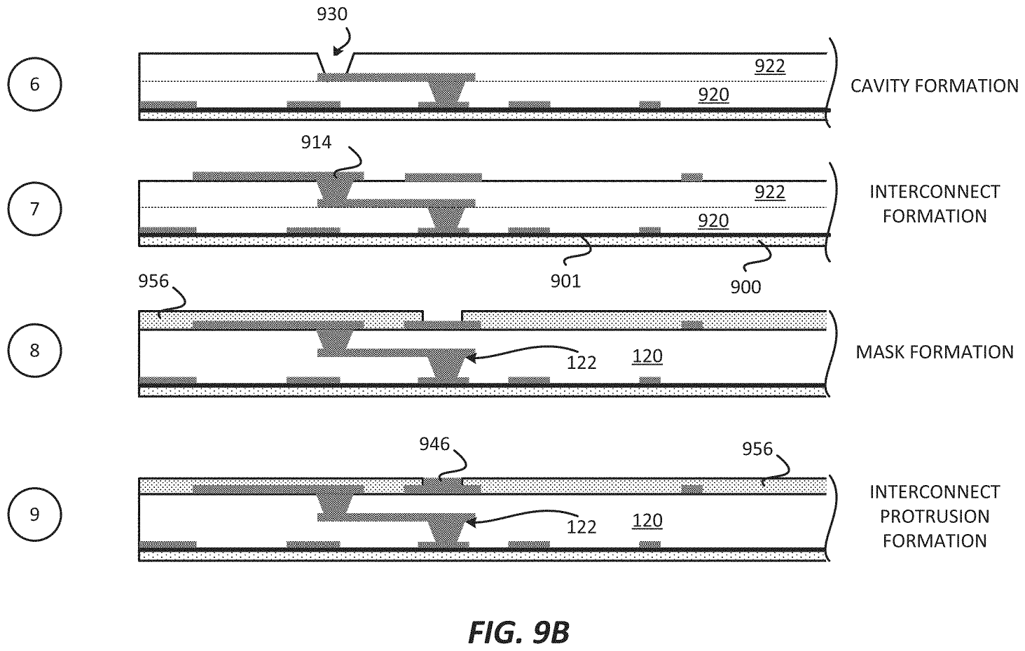

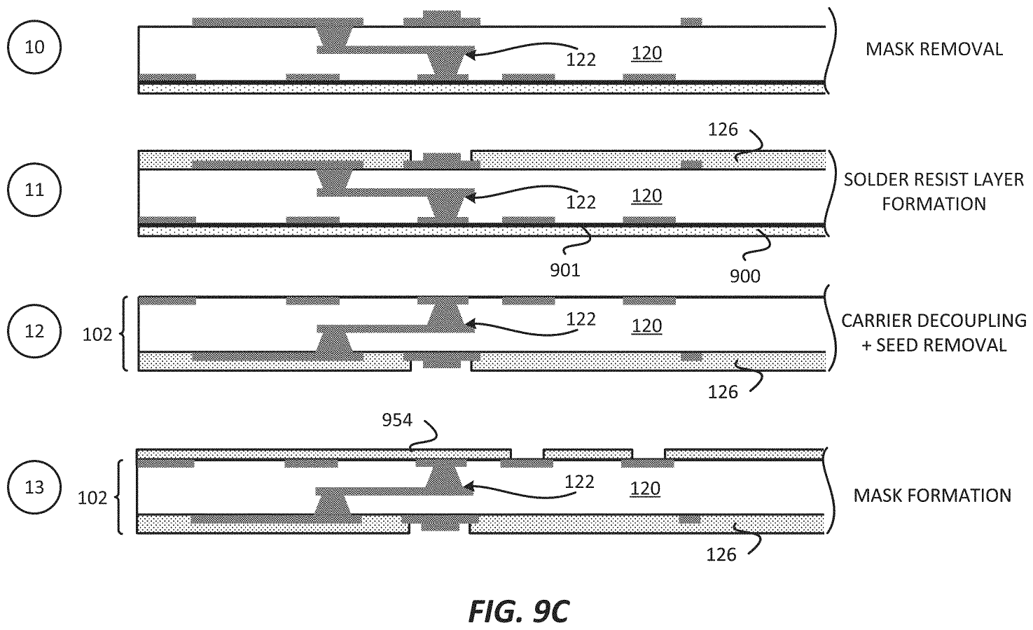

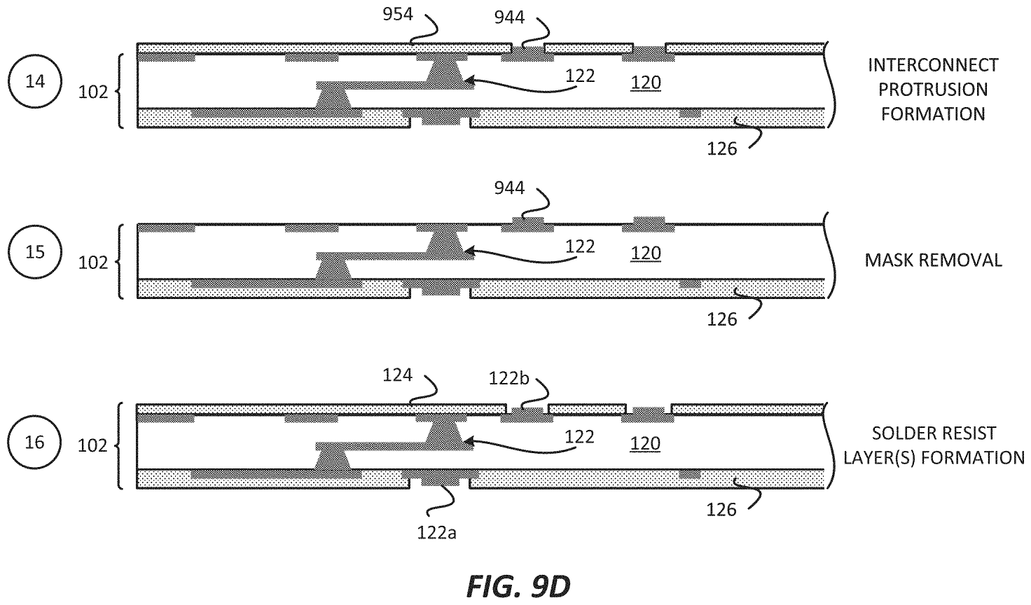

In some implementations, fabricating a substrate includes several processes. FIGS. 9A-9D illustrate an exemplary sequence for providing or fabricating a substrate. In some implementations, the sequence of FIGS. 9A-9D may be used to provide or fabricate the substrate 102. However, the process of FIGS. 9A-9D may be used to fabricate any of the substrates described in the disclosure.

It should be noted that the sequence of FIGS. 9A-9D may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 9A, illustrates a state after a carrier 900 is provided. A seed layer 901 and interconnects 902 may be located over the carrier 900. The interconnects 902 may be located over the seed layer 901. A masking process, a plating process and etching process may be used to form the interconnects 902. In some implementations, the carrier 900 may be provided with the seed layer 901 and a metal layer that is patterned to form the interconnects 902. The interconnects 902 may represent at least some of the interconnects from the plurality of interconnects 122. The interconnects 902 may include an interconnect that represent portions of a pad interconnect.

Stage 2 illustrates a state after a dielectric layer 920 is formed over the carrier 900, the seed layer 901 and the interconnects 902. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

Stage 3 illustrates a state after a plurality of cavities 910 is formed in the dielectric layer 920. The plurality of cavities 910 may be formed using an etching process (e.g., photo etching process) or laser process.

Stage 4 illustrates a state after interconnects 912 are formed in and over the dielectric layer 920, including in and over the plurality of cavities 910. For example, a via, pad and/or traces may be formed. A masking process, a plating process and/or an etching process may be used to form the interconnects.

Stage 5 illustrates a state after a dielectric layer 922 is formed over the dielectric layer 920 and the interconnects 912. A deposition and/or lamination process may be used to form the dielectric layer 922. The dielectric layer 922 may include prepreg and/or polyimide. The dielectric layer 922 may include a photo-imageable dielectric. However, different implementations may use different materials for the dielectric layer.

Stage 6, as shown in FIG. 9B, illustrates a state after a plurality of cavities 930 is formed in the dielectric layer 922. The plurality of cavities 930 may be formed using an etching process (e.g., photo etching process) or laser process.

Stage 7 illustrates a state after interconnects 914 are formed in and over the dielectric layer 922, including in and over the plurality of cavities 930. For example, a via interconnect, a pad interconnect and/or trace interconnects may be formed. A masking process, a plating process and/or an etching process may be used to form the interconnects. The plurality of interconnects 902, the plurality of interconnects 912, and/or the plurality of interconnects 914 may be represented by the plurality of interconnects 122. The dielectric layer 920 and/or the dielectric layer 922 may be represented by the at least one dielectric layer 120. The at least one dielectric layer 120 may include a photo-imageable dielectric. The at least one dielectric layer 120 may include prepreg and/or polyimide. It is noted that additional dielectric layers and interconnects may be formed by iteratively performing stages 5-7.

Stage 8 illustrates a state after a mask 956 is formed over the at least one dielectric layer 120. A deposition and/or a lamination process may be used to form the mask 956 over a surface of the at least one dielectric layer 120.

Stage 9 illustrates a state after an interconnect portion 946 is formed over the plurality of interconnects 914. For example, the interconnect portion 946 may be formed over a pad interconnect from the plurality of interconnects 914 (which may be part of/represented by the plurality of interconnects 122). The interconnect portion 946 may represent a protrusion. The combination of the interconnect portion 946 and a pad interconnect may form a pad interconnect with a protrusion. A plating process and/or an etching process may be used to form the interconnect portion 946. More than one pad interconnect with a protrusion may be formed. There may or may not be interface(s) between the interconnect portion 946 and the pad interconnect from the plurality of interconnects 914.

Stage 10, as shown in FIG. 9C, illustrates a state after the mask 956 has been removed. A decoupling process may be used to remove the mask 956.

Stage 11 illustrates a state after the solder resist layer 126 is formed over the at least one dielectric layer 120. A deposition process may be used to form the solder resist layer 126. The solder resist layer 126 may have a thickness that is equal or greater than the thickness of a pad interconnect with a protrusion. The solder resist layer 126 may be formed such that the solder resist layer 126 may be located over part of a first portion of a pad interconnect that includes a protrusion, as described for example, in FIG. 2.

Stage 12 illustrates a state after the carrier 900 is decoupled (e.g., detached, removed, grinded out) from the at least one dielectric layer 120 and the seed layer 901, portions of the seed layer 901 are removed (e.g., etched out), leaving the substrate 102 that includes the at least one dielectric layer 120, the plurality of interconnects 122 and the solder resist layer 126.

Stage 13 illustrates a state after a mask 954 is formed over the at least one dielectric layer 120. A deposition and/or a lamination process may be used to form the mask 954 over a surface of the at least one dielectric layer 120.

Stage 14, as shown in FIG. 9D, illustrates a state after an interconnect portion 944 is formed over the plurality of interconnects 902. For example, the interconnect portion 944 may be formed over a pad interconnect from the plurality of interconnects 902 (which may be part of/represented by the plurality of interconnects 122). The interconnect portion 944 may represent a protrusion. The combination of the interconnect portion 944 and a pad interconnect may form a pad interconnect with a protrusion. A plating process and/or an etching process may be used to form the interconnect portion 944. More than one pad interconnect with a protrusion may be formed. There may or may not be interface(s) between the interconnect portion 944 and the pad interconnect from the plurality of interconnects 902.

Stage 15 illustrates a state after the mask 954 has been removed. A decoupling process may be used to remove the mask 954.

Stage 16 illustrates a state after the solder resist layer 124 is formed over the at least one dielectric layer 120. A deposition process may be used to form the solder resist layer 124. The solder resist layer 124 may have a thickness that is equal or greater than the thickness of a pad interconnect with a protrusion. The solder resist layer 124 may be formed such that the solder resist layer 124 may be located over part of a first portion of a pad interconnect that includes a protrusion, as described for example, in FIG. 2. Stage 16 may illustrate a substrate that includes at least one dielectric layer 120, a pad interconnect 122a, a pad interconnect 122b, a solder resist layer 124 and a solder resist layer 126.

Different implementations may use different processes for forming the metal layer(s). In some implementations, a chemical vapor deposition (CVD) process and/or a physical vapor deposition (PVD) process for forming the metal layer(s). For example, a sputtering process, a spray coating process, and/or a plating process may be used to form the metal layer(s). The process of forming one or more interconnects may include desmearing, masking, mask removal, and/or etching.

### Exemplary Flow Diagram of a Method for Fabricating a Substrate

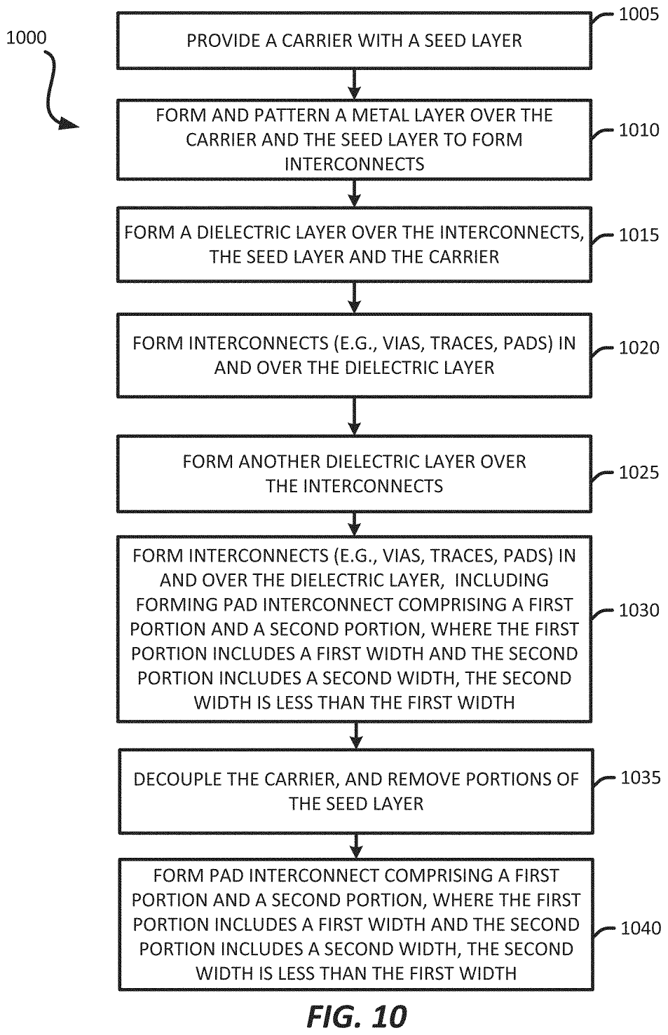

In some implementations, fabricating a substrate includes several processes. FIG. 10 illustrates an exemplary flow diagram of a method 1000 for providing or fabricating a substrate. In some implementations, the method 1000 of FIG. 10 may be used to provide or fabricate the substrate(s) of FIGS. 1-2. For example, the method 1000 of FIG. 10 may be used to fabricate the substrate 102.

It should be noted that the method 1000 of FIG. 10 may combine one or more processes in order to simplify and/or clarify the method for providing or fabricating a substrate. In some implementations, the order of the processes may be changed or modified.

The method provides (at 1005) a carrier (e.g., 900). Different implementations may use different materials for the carrier 900. The carrier 900 may include a seed layer (e.g., 901). The seed layer 901 may include a metal (e.g., copper). The carrier may include a substrate, glass, quartz and/or carrier tape. Stage 1 of FIG. 9A illustrates and describes an example of a carrier with a seed layer that is provided.

The method forms and patterns (at 1010) interconnects over the carrier 900 and the seed layer 901. A metal layer may be patterned to form interconnects. A plating process may be used to form the metal layer and interconnects. In some implementations, the carrier and seed layer may include a metal layer. The metal layer is located over the seed layer and the metal layer may be patterned to form interconnects (e.g., 902). Stage 1 of FIG. 9A illustrates and describes an example of interconnects over a seed layer and a carrier.

The method forms (at 1015) a dielectric layer 920 over the seed layer 901, the carrier 900 and the interconnects 902. A deposition and/or lamination process may be used to form the dielectric layer 920. The dielectric layer 920 may include prepreg and/or polyimide. The dielectric layer 920 may include a photo-imageable dielectric. Forming the dielectric layer 920 may also include forming a plurality of cavities (e.g., 910) in the dielectric layer 920. The plurality of cavities may be formed using an etching process (e.g., photo etching) or laser process. Stages 2-3 of FIG. 9A illustrate and describe an example of forming a dielectric layer and cavities in the dielectric layer.

The method forms (at 1020) interconnects in and over the dielectric layer. For example, the interconnects 912 may be formed in and over the dielectric layer 920. A plating process may be used to form the interconnects. Forming interconnects may include providing a patterned metal layer over and/or in the dielectric layer. Forming interconnects may also include forming interconnects in cavities of the dielectric layer. Stage 4 of FIG. 9A illustrates and describes an example of forming interconnects in and over a dielectric layer.

The method forms (at 1025) a dielectric layer 922 over the dielectric layer 920 and the interconnects 912. A deposition and/or lamination process may be used to form the dielectric layer 922. The dielectric layer 922 may include prepreg and/or polyimide. The dielectric layer 922 may include a photo-imageable dielectric. Forming the dielectric layer 922 may also include forming a plurality of cavities (e.g., 930) in the dielectric layer 922. The plurality of cavities may be formed using an etching process (e.g., photo etching) or laser process. Stages 5-6 of FIGS. 9A-9B illustrate and describe an example of forming a dielectric layer and cavities in the dielectric layer.

The method forms (at 1030) interconnects in and over the dielectric layer. For example, the interconnects 914 may be formed in and over the dielectric layer 922. A plating process may be used to form the interconnects. Forming interconnects may include providing a patterned metal layer over and/or in the dielectric layer. Forming interconnects may also include forming interconnects in cavities of the dielectric layer. Stage 7 of FIG. 9B illustrates and describes an example of forming interconnects in and over a dielectric layer.

The method may also form (at 1030) pad interconnects comprising a protrusion over a second surface of the at least one dielectric layer. For example, the method may form a pad interconnect comprising a first portion and a second portion, where the first portion includes a first width and the second portion includes a second width that is less than the first width. Forming a pad interconnect comprising a protrusion may include forming a mask over a dielectric layer and forming an interconnect portion over a pad interconnect. The interconnect portion may become part of the pad interconnect. Once the interconnect portion is formed, the mask may be removed leaving the pad interconnect with a protrusion. Stages 8-10 of FIGS. 9B and 9C illustrate and describe an example of forming pad interconnects with protrusions.

In some implementations, the method may also form (at 1030) a solder resist layer (e.g., 126) over a second surface of the at least one dielectric layer 120. The solder resist layer may be formed over part of a first portion of a pad interconnect that includes a protrusion. A deposition process may be used to form the solder resist layer. Stage 11 of FIG. 9C illustrates and describes an example of forming a solder resist layer.

The method decouples (at 1035) the carrier (e.g., 900) from the seed layer (e.g., 901). The carrier 900 may be detached and/or grounded out. The method may also remove (at 1035) portions of the seed layer (e.g., 901). An etching process may be used to remove portions of the seed layer 901. Stage 12 of FIG. 9C illustrates and describes an example of decoupling a carrier and seed layer removal.

The method forms (at 1040) pad interconnects comprising a protrusion over a first surface of the at least one dielectric layer. For example, the method may form a pad interconnect comprising a first portion and a second portion, where the first portion includes a first width and the second portion includes a second width that is less than the first width. Forming a pad interconnect comprising a protrusion may include forming a mask over a dielectric layer and forming an interconnect portion over a pad interconnect. The interconnect portion may become part of the pad interconnect. Once the interconnect portion is formed, the mask may be removed leaving the pad interconnect with a protrusion. Stages 13-15 of FIGS. 9C and 9D illustrate and describe an example of forming pad interconnects with protrusions.

In some implementations, the method may form a solder resist layer (e.g., 124) over a first surface of the at least one dielectric layer 120. The solder resist layer may be formed over part of a first portion of a pad interconnect that includes a protrusion. A deposition process may be used to form the solder resist layer. Stage 16 of FIG. 9D illustrates and describes an example of forming a solder resist layer.

Different implementations may use different processes for forming the metal layer(s). In some implementations, a chemical vapor deposition (CVD) process and/or a physical vapor deposition (PVD) process for forming the metal layer(s). For example, a sputtering process, a spray coating process, and/or a plating process may be used to form the metal layer(s). The process of forming one or more interconnects may include desmearing, masking, mask removal, and/or etching.

### Exemplary Sequence for Fabricating a Substrate

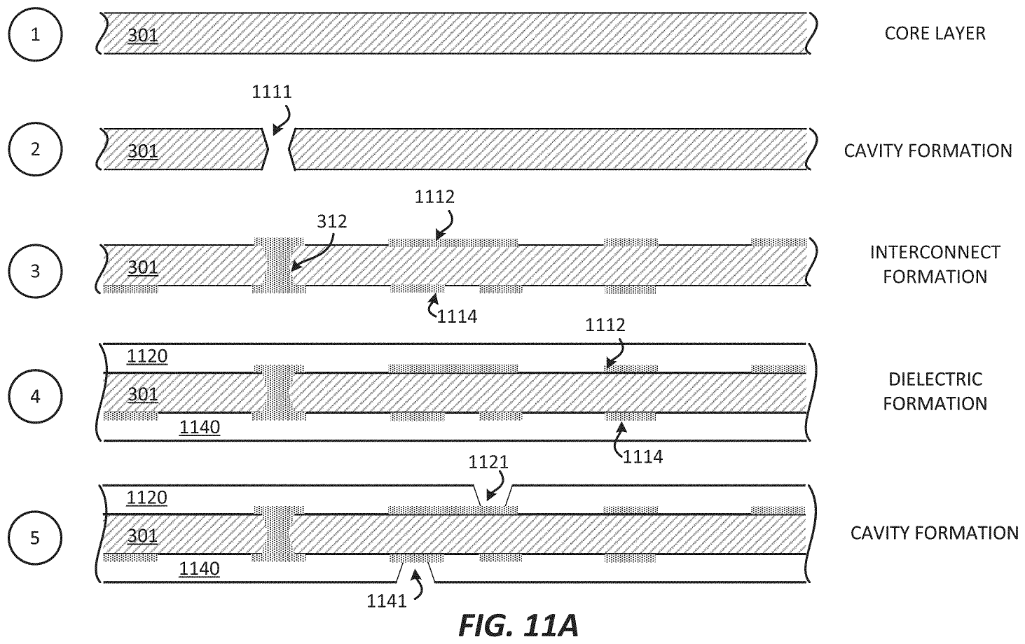

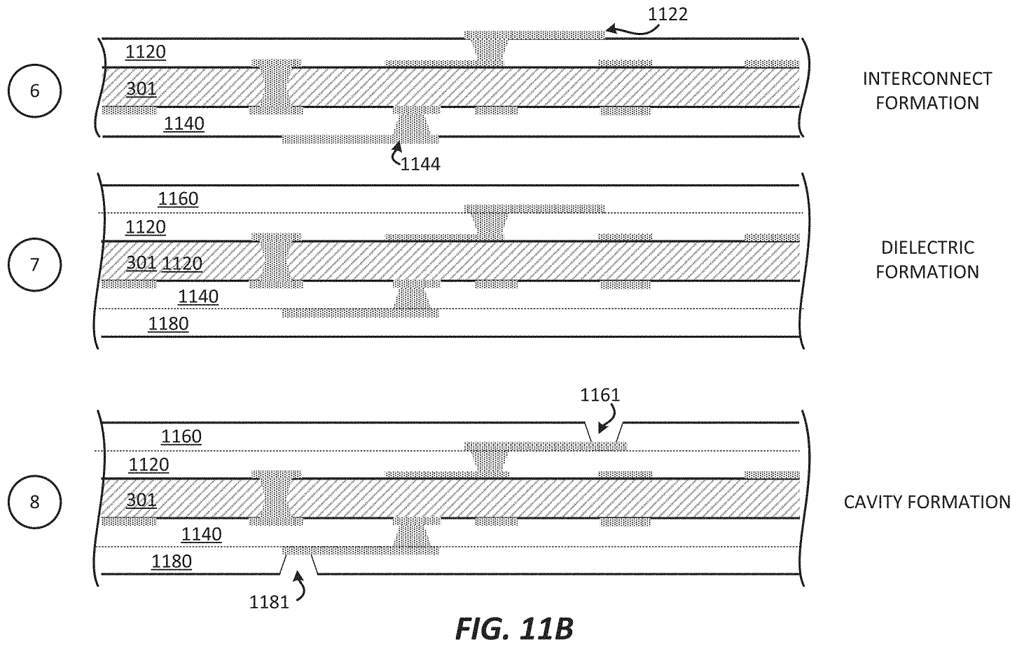

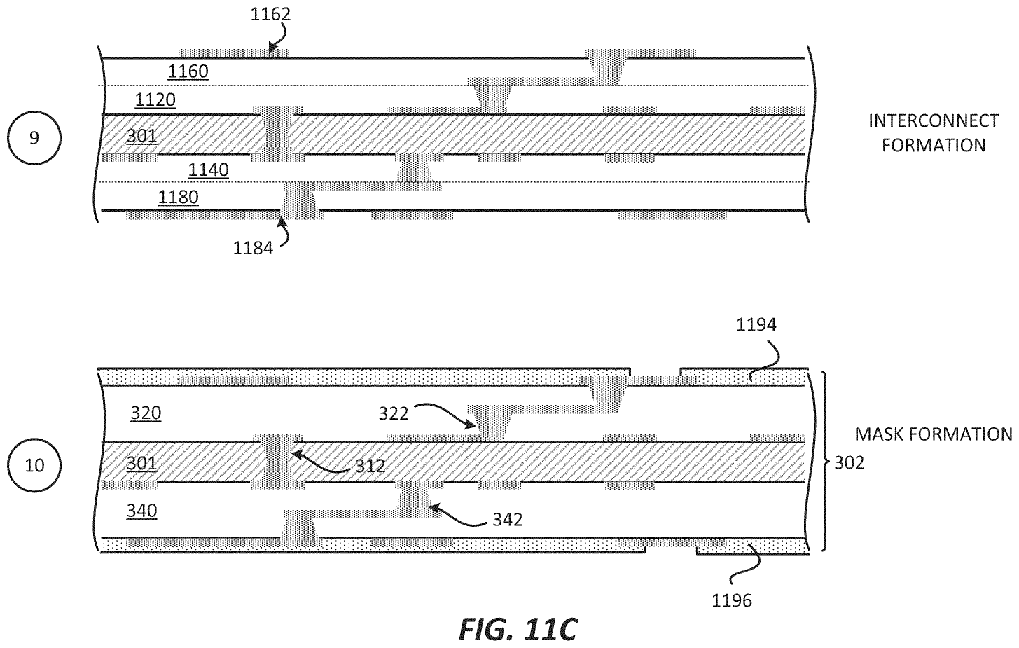

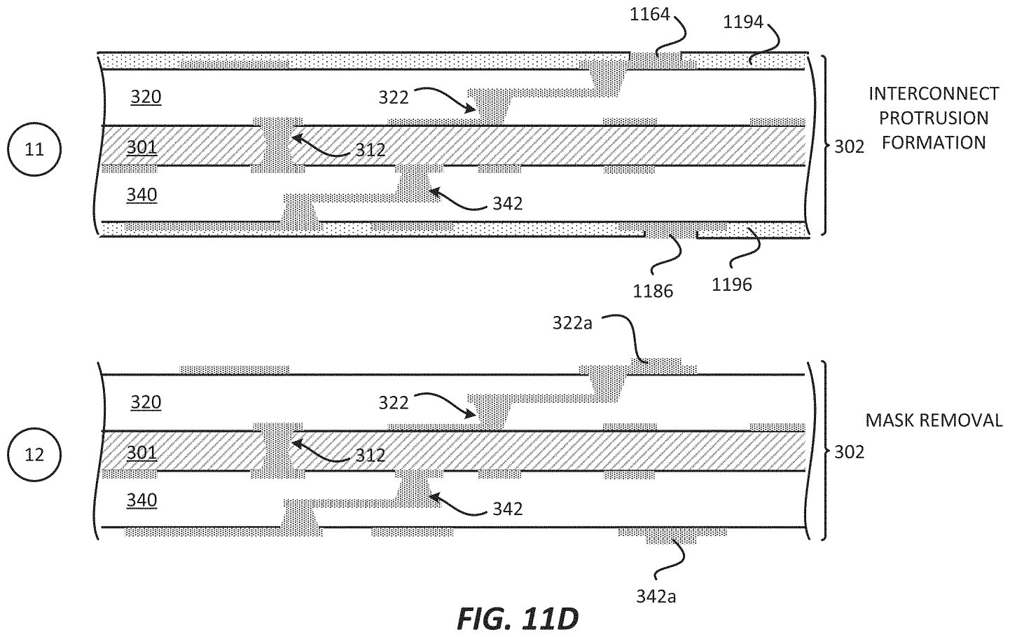

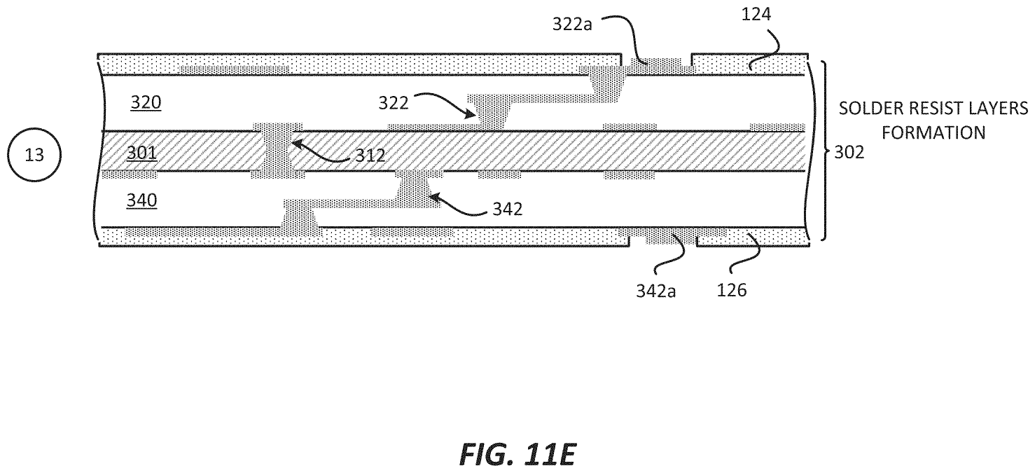

In some implementations, fabricating a substrate includes several processes. FIGS. 11A-11E illustrate an exemplary sequence for providing or fabricating a substrate. In some implementations, the sequence of FIGS. 11A-11E may be used to provide or fabricate the substrate 302. However, the process of FIGS. 11A-11E may be used to fabricate any of the substrates described in the disclosure.

It should be noted that the sequence of FIGS. 11A-11E may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 11A, illustrates a state after a core layer 301 is provided. A first seed layer (not shown) may be located over a first surface (e.g., top surface) of the core layer 301 and a second seed layer (not shown) may be located over a second surface (e.g., bottom surface) of the core layer 301. A seed layer may include a metal layer (e.g., copper layer). When a seed layer is present, interconnects and/or dielectric layers may be formed over the core layer 301 and the seed layer(s).

Stage 2 illustrates a state after a plurality of cavities 1111 is formed in the core layer 301. A laser process (e.g., laser ablation) may be used to form at least one cavity that extends through the thickness of the core layer 301. The plurality of cavities 1111 may be formed through the first surface and the second surface of the core layer 301.

Stage 3 illustrates a state after a plurality of core interconnects 312 is formed in the plurality of cavities 1111. Stage 3 also illustrates a state after a plurality of interconnects 1112 is formed over the first surface of the core layer 301, and a plurality of interconnects 1114 is formed over the second surface of the core layer 301. A plating process may be used to form the core interconnects 312. A plating process and etching process may be used to form the interconnects 1112 and/or 1114. Some of the interconnects 1112 and/or 1114 may be coupled to the core interconnects 312.

Stage 4 illustrates a state after a dielectric layer 1120 is formed over the first surface of the core layer 301 and the plurality of interconnects 1112. Stage 4 also illustrates a state after a dielectric layer 1140 is formed over the second surface of the core layer 301 and the plurality of interconnects 1114. A deposition and/or lamination process may be used to form the dielectric layer 1120 and the dielectric layer 1140. The dielectric layer 1120 and/or the dielectric layer 1140 may include polyimide. The dielectric layer 1120 and/or the dielectric layer 1140 may include a photo imageable dielectric. However, different implementations may use different materials for the dielectric layer.

Stage 5 illustrates a state after a plurality of cavities 1121 is formed in the dielectric layer 1120, and a plurality of cavities 1141 is formed in the dielectric layer 1140. The plurality of cavities 1121 and/or the plurality of cavities 1141 may be formed using an etching process (e.g., photo etching process) or laser process.

Stage 6, as shown in FIG. 11B, illustrates a state after a plurality of interconnects 1122 is formed over the dielectric layer 1120, and a plurality of interconnects 1144 is formed over the dielectric layer 1140. A plating process and etching process may be used to form the plurality of interconnects 1122 and/or the plurality of interconnects 1144.

Stage 7 illustrates a state after a dielectric layer 1160 is formed over the dielectric layer 1120 and the plurality of interconnects 1122. Stage 7 also illustrates a state after a dielectric layer 1180 is formed over the dielectric layer 1140 and the plurality of interconnects 1144. A deposition and/or lamination process may be used to form the dielectric layer 1160 and the dielectric layer 1180. The dielectric layer 1160 and/or the dielectric layer 1180 may include polyimide. The dielectric layer 1160 and/or the dielectric layer 1180 may include a photo imageable dielectric. However, different implementations may use different materials for the dielectric layer.

Stage 8 illustrates a state after a plurality of cavities 1161 is formed in the dielectric layer 1160, and a plurality of cavities 1181 is formed in the dielectric layer 1180. The plurality of cavities 1161 and/or the plurality of cavities 1181 may be formed using an etching process (e.g., photo etching process) or laser process.

Stage 9, as shown in FIG. 11C, illustrates a state after a plurality of interconnects 1162 is formed over the dielectric layer 1160, and a plurality of interconnects 1184 is formed over the dielectric layer 1180. A plating process and etching process may be used to form the plurality of interconnects 1162 and/or the plurality of interconnects 1184. The dielectric layer 1120 and/or the dielectric layer 1160 may be represented by the at least one dielectric layer 320. The plurality of interconnects 1112, the plurality of interconnects 1122 and/or the plurality of interconnects 1162 may be represented by the plurality of interconnects 322. The dielectric layer 1140 and/or the dielectric layer 1180 may be represented by the at least one dielectric layer 340. The plurality of interconnects 1114, the plurality of interconnects 1144 and/or the plurality of interconnects 1184 may be represented by the plurality of interconnects 342.

Stage 10 illustrates a state after the mask 1194 is formed over a first surface of the substrate 302, and a mask 1196 is formed over a second surface of the substrate 302. The mask 1194 may be formed over the at least one dielectric layer 320. The mask 1196 may be formed over the at least one dielectric layer 340. A deposition process may be used to form the mask 1194 and the mask 1196.

Stage 11, as shown in FIG. 11D, illustrates a state after interconnect portions 1164 are formed over the plurality of interconnects 322. The interconnect portions 1164 may be formed over at least some of the pad interconnects from the plurality of interconnects 322. The interconnect portions 1164 may represent protrusions. The interconnect portions 1164 in combination with the pad interconnects may form and/or define a pad interconnect with a protrusion over a first surface of the substrate 302. For example, the combination of the interconnect portions 1164 and the pad interconnects may form and/or define a pad interconnect that includes a first portion and a second portion. A plating process and/or an etching process may be used to form the interconnect portions.

Stage 11 also illustrates a state after interconnect portions 1186 are formed over the plurality of interconnects 342. The interconnect portions 1186 may be formed over at least some of the pad interconnects from the plurality of interconnects 342. The interconnect portions 1186 may represent protrusions. The interconnect portions 1186 in combination with the pad interconnects may form and/or define a pad interconnect with a protrusion over a second surface of the substrate 302. For example, the combination of the interconnect portions 1186 and the pad interconnects may form and/or define a pad interconnect that includes a first portion and a second portion. A plating process and/or an etching process may be used to form the interconnect portions.

Stage 12 illustrates a state after the mask 1194 and the mask 1196 have been removed. The mask 1194 may be decoupled from the at least one dielectric layer 320, leaving at least the pad interconnect 322a. The mask 1196 may be decoupled from the at least one dielectric layer 340, leaving at least the pad interconnect 342a.

Stage 13 illustrates a state after the solder resist layer 124 is formed over the at least one dielectric layer 320 and the solder resist layer 126 is formed over the at least one dielectric layer 340. A deposition process may be used to form the solder resist layer 124 and the solder resist layer 126. The solder resist layer 124 may be formed such that the solder resist layer 124 may be located over part of a first portion of a pad interconnect that includes a protrusion, as described for example, in FIG. 4. The solder resist layer 126 may be formed such that the solder resist layer 126 may be located over part of a first portion of a pad interconnect that includes a protrusion, as described for example, in FIG. 4. In some implementations, none or one solder resist layer may be formed over the at least one dielectric layer 320 and/or the at least one dielectric layer 340. The solder resist layer 124 and the solder resist layer 126 may considered part of the substrate 302.

Different implementations may use different processes for forming the metal layer(s). In some implementations, a chemical vapor deposition (CVD) process and/or a physical vapor deposition (PVD) process for forming the metal layer(s). For example, a sputtering process, a spray coating process, and/or a plating process may be used to form the metal layer(s). The process of forming one or more interconnects may include desmearing, masking, mask removal, and/or etching.

### Exemplary Flow Diagram of a Method for Fabricating a Substrate

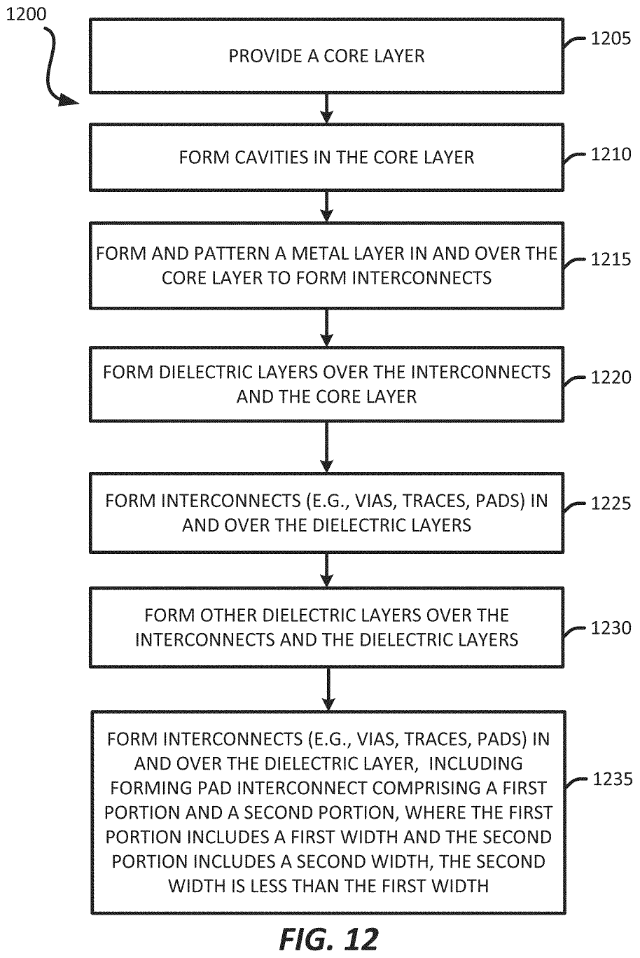

In some implementations, fabricating a substrate includes several processes. FIG. 12 illustrates an exemplary flow diagram of a method 1200 for providing or fabricating a substrate. In some implementations, the method 1200 of FIG. 12 may be used to provide or fabricate the substrate(s) of FIGS. 3-4. For example, the method 1200 of FIG. 12 may be used to fabricate the substrate 302.

It should be noted that the method 1200 of FIG. 12 may combine one or more processes in order to simplify and/or clarify the method for providing or fabricating a substrate. In some implementations, the order of the processes may be changed or modified.

The method provides (at 1205) a core layer (e.g., 301). Different implementations may use different materials for the core layer 301. In some implementations, a first seed layer (not shown) may be located over a first surface (e.g., top surface) of the core layer 301 and a second seed layer (e.g., not shown) may be located over a second surface (e.g., bottom surface) of the core layer 301. A seed layer may include a metal layer (e.g., copper layer). Stage 1 of FIG. 11A illustrates and describes an example of a core layer that is provided.

The method forms (at 1210) cavities (e.g., 1111) in the core layer (e.g., 301). A laser process (e.g., laser ablation) may be used to form at least one cavity that extends through the thickness of the core layer 301. The cavities 1111 may be formed through the first surface and the second surface of the core layer 301. Stage 2 of FIG. 11A illustrates and describes an example of forming cavities in a core layer.

The method forms and patterns (at 1215) metal layer(s) in and over the core layer to forms a plurality of interconnects. For example, a plurality of core interconnects 312 may be formed in the plurality of cavities 1111. A plurality of interconnects 1112 may be formed over the first surface of the core layer 301, and a plurality of interconnects 1114 may be formed over the second surface of the core layer 301. A plating process and etching process may be used to form the interconnects 1112 and/or 1114. Stage 3 of FIG. 11A illustrates and describes an example of forming interconnects.

The method forms (at 1220) dielectric layers over the core layer. For example, a dielectric layer 1120 may be formed over the first surface of the core layer 301 and the plurality of interconnects 1112. A dielectric layer 1140 may be formed over the second surface of the core layer 301 and the plurality of interconnects 1114. A deposition and/or lamination process may be used to form the dielectric layer 1120 and the dielectric layer 1140. The dielectric layer 1120 and/or the dielectric layer 1140 may include polyimide. However, different implementations may use different materials for the dielectric layer. Stage 4 of FIG. 11A illustrates and describes an example of forming dielectric layers.

The method forms (at 1225) interconnects in and/or over dielectric layers. Forming interconnects may include forming cavities in the dielectric layers. For example, a plurality of cavities 1121 may be formed in the dielectric layer 1120, and a plurality of cavities 1141 may be formed in the dielectric layer 1140. The plurality of cavities 1121 and/or the plurality of cavities 1141 may be formed using an etching process (e.g., photo etching process) or laser process. Forming a plurality of interconnects may include forming a plurality of interconnects 1122 over the dielectric layer 1120, and forming a plurality of interconnects 1144 over the dielectric layer 1140. A plating process and etching process may be used to form the plurality of interconnects 1122 and/or the plurality of interconnects 1144. Stages 5-6 of FIGS. 11A-11B illustrate and describe an example of forming cavities and interconnects.

The method forms (at 1230) additional dielectric layers (e.g., 1160, 1180) over dielectric layers and interconnects. For example, a dielectric layer 1160 may be formed over the dielectric layer 1120 and the plurality of interconnects 1122. A dielectric layer 1180 may be formed over the dielectric layer 1140 and the plurality of interconnects 1144. A deposition and/or lamination process may be used to form the dielectric layer 1160 and the dielectric layer 1180. The dielectric layer 1160 and/or the dielectric layer 1180 may include polyimide. However, different implementations may use different materials for the dielectric layer. Stage 7 of FIG. 11B illustrates and describes an example of forming dielectric layers.

The method forms (at 1235) interconnects in and/or over dielectric layers.

Forming interconnects may include forming cavities in the dielectric layers. For example, a plurality of cavities 1161 may be formed in the dielectric layer 1160, and a plurality of cavities 1181 may be formed in the dielectric layer 1180. The plurality of cavities 1161 and/or the plurality of cavities 1181 may be formed using an etching process (e.g., photo etching process) or laser process. A plurality of interconnects 1162 may be formed over the dielectric layer 1160, and a plurality of interconnects 1184 may be formed over the dielectric layer 1180. A masking process, a plating process and etching process may be used to form the plurality of interconnects 1162 and/or the plurality of interconnects 1184. Interconnect portions 1164 may be formed over the plurality of interconnects 322. Interconnect portions 1186 are formed over the plurality of interconnects 342.

The dielectric layer 1120 and/or the dielectric layer 1160 may be represented by the at least one dielectric layer 320. The plurality of interconnects 1112, the plurality of interconnects 1122, the plurality of interconnects 1162 and/or the interconnect portions 1164 may be represented by the plurality of interconnects 322. The plurality of interconnects 322 includes the pad interconnect 322a. The pad interconnect 322a may be located over a first surface of the substrate 302. The pad interconnect 322a includes a first portion and a second portion coupled to the first portion. The first portion includes a first width and the second portion includes a second width. The second width is less than the first width. The dielectric layer 1140 and/or the dielectric layer 1180 may be represented by the at least one dielectric layer 340. The plurality of interconnects 1114, the plurality of interconnects 1144, the plurality of interconnects 1184 and/or the interconnect portions 1186 may be represented by the plurality of interconnects 342. The plurality of interconnects 342 includes the pad interconnect 342a. The pad interconnect 342a may be located over a second surface of the substrate 302. The pad interconnect 342a includes a first portion and a second portion coupled to the first portion. The first portion includes a first width and the second portion includes a second width. The second width is less than the first width. Stages 8-12 of FIGS. 11B-11D illustrate and describe an example of forming cavities and interconnects, where at least some of the interconnects include a pad interconnect with a protrusion.

In some implementations, the method may form solder resist layers (e.g., 124, 126) over the substrate (e.g., 302). The solder resist layer (e.g., 124, 126) may be formed such that the solder resist layer (e.g., 124, 126) may be located over part of a first portion of a pad interconnect that includes a protrusion, as described for example, in FIG. 4. Stage 13 of FIG. 11E illustrates and describes an example of forming solder resist layers.

Different implementations may use different processes for forming the metal layer(s). In some implementations, a chemical vapor deposition (CVD) process and/or a physical vapor deposition (PVD) process for forming the metal layer(s). For example, a sputtering process, a spray coating process, and/or a plating process may be used to form the metal layer(s). The process of forming one or more interconnects may include desmearing, masking, mask removal, and/or etching.

Exemplary Sequence for Fabricating a Package Comprising a Substrate with a Pad Interconnect Comprising a Protrusion

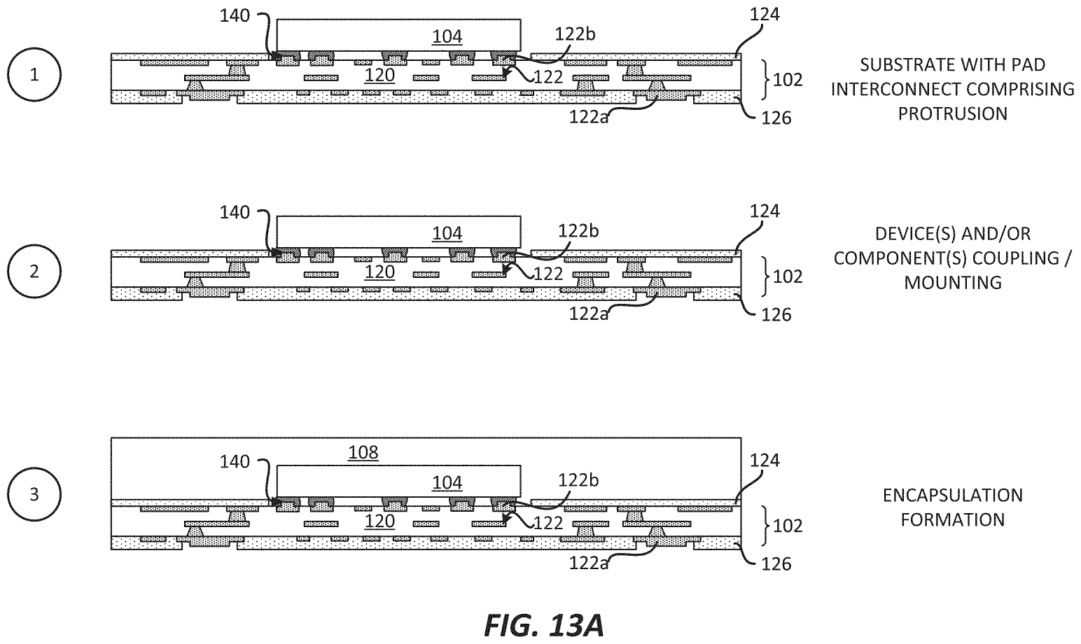

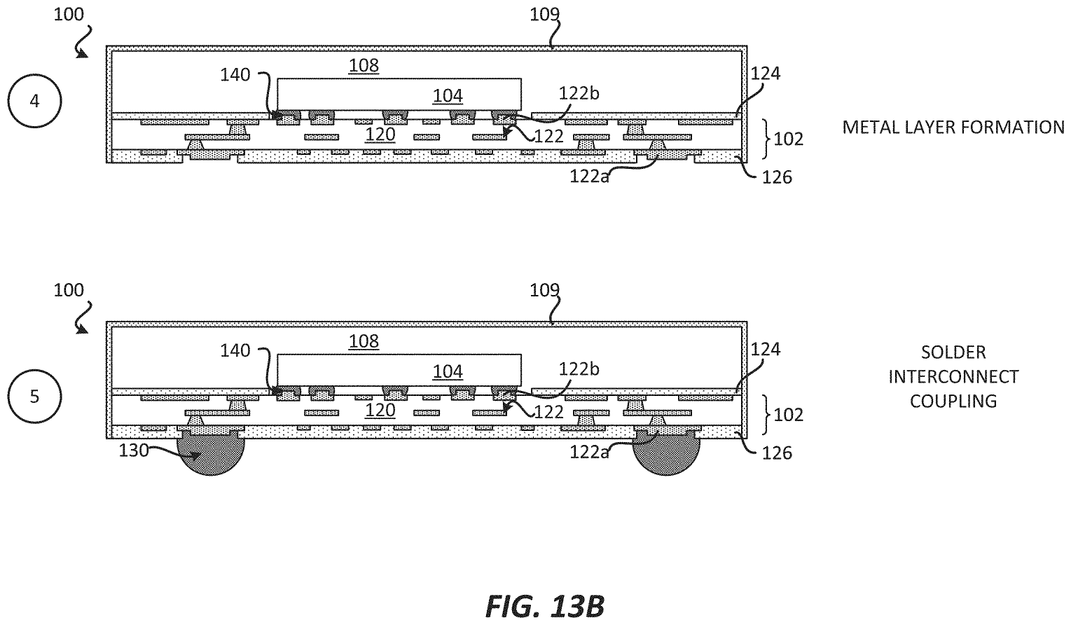

In some implementations, fabricating a package includes several processes. FIGS. 13A-13B illustrate an exemplary sequence for providing or fabricating a package that includes a substrate with interconnects. In some implementations, the sequence of FIGS. 13A-13B may be used to provide or fabricate the package 100. However, the process of FIGS. 13A-13B may be used to fabricate any of the packages described in the disclosure.

It should be noted that the sequence of FIGS. 13A-13B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 13A illustrates a state after a substrate 102 is provided. The substrate 102 includes at least one dielectric layer 120, a plurality of interconnects 122, a solder resist layer 124, and a solder resist layer 126.

As mentioned in FIG. 2, the plurality of interconnects 122 may include the pad interconnect 122a and the pad interconnect 122b. Different implementations may use different substrates with different numbers of metal layers. The substrate 102 may be fabricated using the method as described in FIGS. 9A-9D.

Stage 2 illustrates a state after the integrated device 104 is coupled to the substrate 102 through the plurality of solder interconnects 140. A solder reflow process may be used to couple the integrated device 104 to the substrate 102. The integrated device 104 may be coupled to the first surface (e.g., top surface) of the substrate 102. FIG. 2 illustrates an example of how the integrated device 104 may be coupled to the substrate 102. Different implementations may couple different components and/or devices to the substrate 102.

Stage 3 illustrates a state after an encapsulation layer 108 is provided (e.g., formed) over the first surface of the substrate 102. The encapsulation layer 108 may encapsulate the integrated device 104. The encapsulation layer 108 may include a mold, a resin and/or an epoxy. A compression molding process, a transfer molding process, or a liquid molding process may be used to form the encapsulation layer 108. The encapsulation layer 108 may be photo etchable. The encapsulation layer 108 may be a means for encapsulation.

Stage 4, as shown in FIG. 13B, illustrates a state after a metal layer 109 is formed over a surface of the encapsulation layer 108 and a side surface of the substrate 102. The metal layer 109 may be configured as an electromagnetic interference (EMI) shield. The metal layer 109 may be configured to be coupled to ground. The metal layer 109 may be coupled to an interconnect from the plurality of interconnects 122 of the substrate 102. A sputtering process may be used to form the metal layer.

Stage 5 illustrates a state after a plurality of solder interconnects 130 is coupled to the substrate 102. A solder reflow process may be used to couple the plurality of solder interconnects 130 to the substrate 102. The plurality of solder interconnects 130 may be coupled to the plurality of interconnects 122.

The packages (e.g., 100) described in the disclosure may be fabricated one at a time or may be fabricated together as part of one or more wafers and then singulated into individual packages.

Exemplary Sequence for Fabricating a Package Comprising a Substrate with a Pad Interconnect Comprising a Protrusion

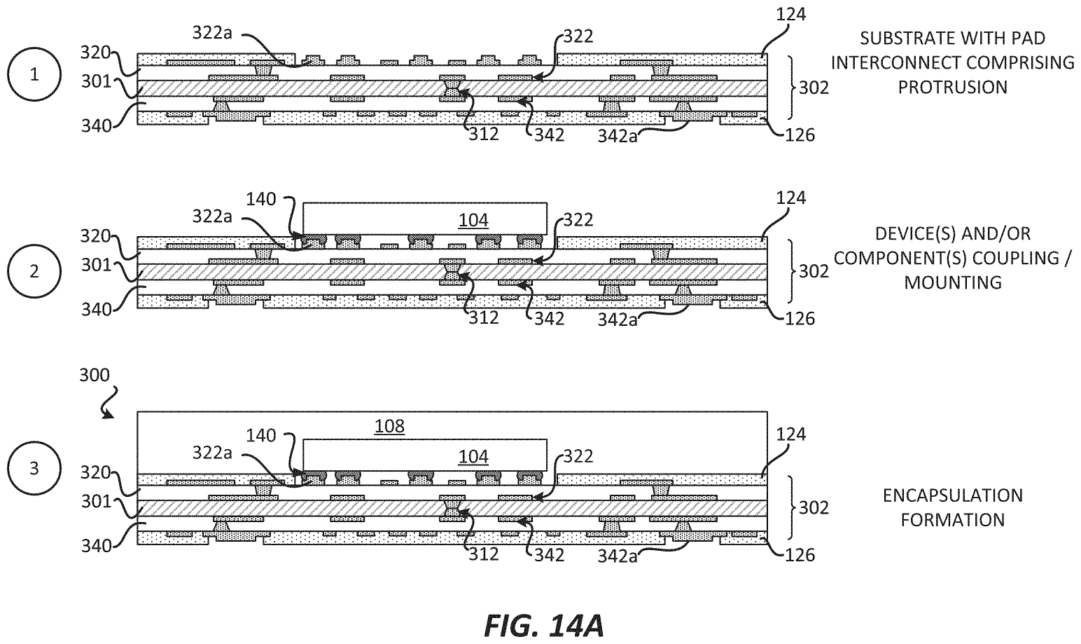

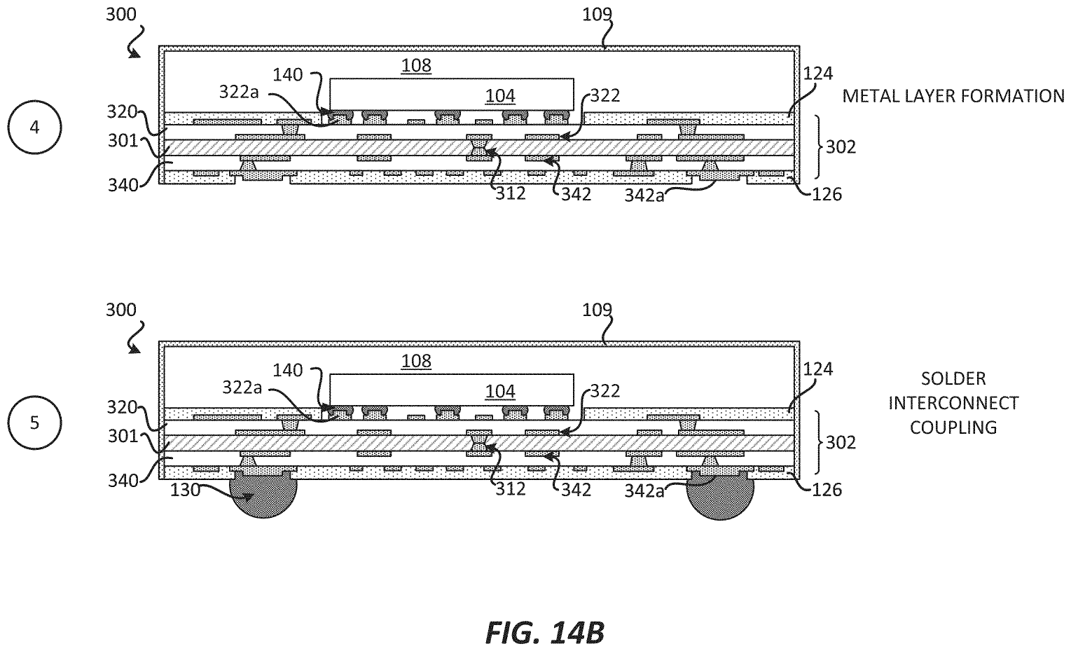

In some implementations, fabricating a package includes several processes. FIGS. 14A-14B illustrates an exemplary sequence for providing or fabricating a package that includes a substrate with interconnects. In some implementations, the sequence of FIGS. 14A-14B may be used to provide or fabricate the package 300. However, the process of FIGS. 14A-14B may be used to fabricate any of the packages described in the disclosure.

It should be noted that the sequence of FIGS. 14A-14B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 14 illustrates a state after a substrate 302 is provided. The substrate 302 includes a core layer 301, at least one dielectric layer 320, at least one dielectric layer 340, a plurality of core interconnects 312, a plurality of interconnects 322, a plurality of interconnects 342, a solder resist layer 124, and a solder resist layer 126. The substrate 302 may include a first surface (e.g., top surface) and a second surface (e.g., bottom surface). The solder resist layer 124 may be located over the first surface of the substrate 302. The solder resist layer 126 may be located over the second surface of the substrate 302. The plurality of interconnects 322 includes a pad interconnect 322a. The plurality of interconnects 342 includes a pad interconnect 342a. Different implementations may use different substrates with different numbers of metal layers. The substrate 302 may be fabricated using the method as described in FIGS. 11A-11E.

Stage 2 illustrates a state after the integrated device 104 is coupled to the substrate 302 through the plurality of solder interconnects 140. A solder reflow process may be used to couple the integrated device 104 to the substrate 302. The integrated device 104 may be coupled to the first surface (e.g., top surface) of the substrate 302. FIG. 4 illustrates an example of how the integrated device 104 may be coupled to the substrate 302. Different implementations may couple different components and/or devices to the substrate 302.

Stage 3 illustrates a state after an encapsulation layer 108 is provided (e.g., formed) over the first surface of the substrate 302. The encapsulation layer 108 may encapsulate the integrated device 104. The encapsulation layer 108 may include a mold, a resin and/or an epoxy. A compression molding process, a transfer molding process, or a liquid molding process may be used to form the encapsulation layer 108. The encapsulation layer 108 may be photo etchable. The encapsulation layer 108 may be a means for encapsulation.

Stage 4, as shown in FIG. 14B, illustrates a state after a metal layer 109 is formed over a surface of the encapsulation layer 108 and a side surface of the substrate 302. The metal layer 109 may be configured as an electromagnetic interference (EMI) shield. The metal layer 109 may be configured to be coupled to ground. The metal layer 109 may be coupled to an interconnect from the plurality of interconnects 322 and/or an interconnect from the plurality of interconnects 342 of the substrate 302. A sputtering process may be used to form the metal layer.

Stage 5 illustrates a state after a plurality of solder interconnects 130 is coupled to the substrate 302. A solder reflow process may be used to couple the plurality of solder interconnects 130 to the substrate 302. The plurality of solder interconnects 130 may be coupled to the plurality of interconnects 342.

The packages (e.g., 300) described in the disclosure may be fabricated one at a time or may be fabricated together as part of one or more wafers and then singulated into individual packages.

Exemplary Flow Diagram of a Method for Fabricating a Package Comprising a Substrate with a Pad Interconnect Comprising a Protrusion

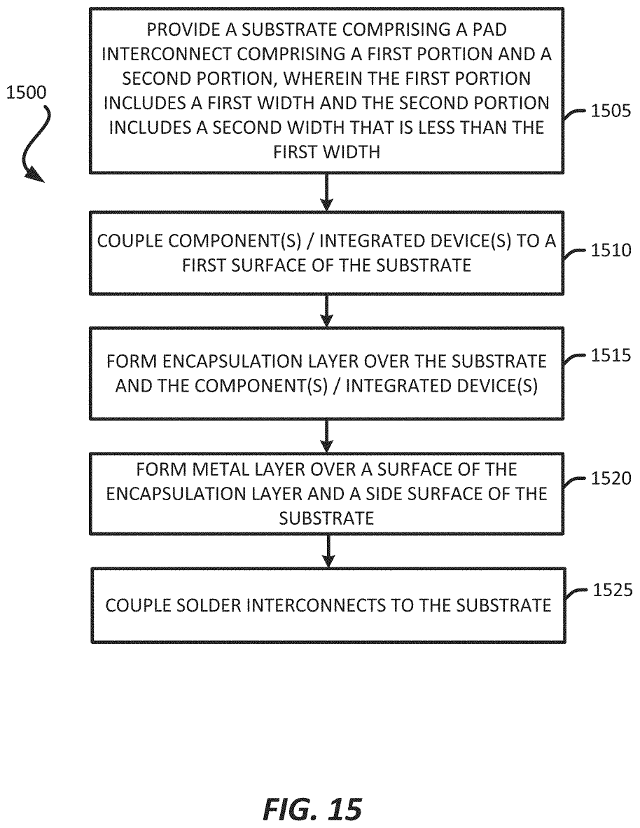

In some implementations, fabricating a package includes several processes. FIG. 15 illustrates an exemplary flow diagram of a method 1500 for providing or fabricating a package comprising a substrate with interconnects. In some implementations, the method 1500 of FIG. 15 may be used to provide or fabricate the package 100 described in the disclosure. However, the method 1500 may be used to provide or fabricate any of the packages (e.g., 300) described in the disclosure.

It should be noted that the method of FIG. 15 may combine one or more processes in order to simplify and/or clarify the method for providing or fabricating a package. In some implementations, the order of the processes may be changed or modified.

The method provides (at 1505) a substrate (e.g., 102, 302). The substrate may be provided by a supplier or fabricated. The substrate 102 includes at least one dielectric layer 120, a plurality of interconnects 122, a solder resist layer 124, and a solder resist layer 126. The substrate 302 includes a core layer 301, at least one dielectric layer 320, at least one dielectric layer 340, a plurality of core interconnects 312, a plurality of interconnects 322, a plurality of interconnects 342, a solder resist layer 124, and a solder resist layer 126. The substrate may include at least one pad interconnect that includes a protrusion, as described in at least FIGS. 1-5. Different implementations Different implementations may use different processes to fabricate the substrate. FIGS. 9A-9D illustrates and describes an example of fabricating a substrate with interconnects. FIGS. 11A-11E illustrates and describes an example of fabricating a cored substrate with interconnects. Stage 1 of FIG. 13A, illustrates and describes an example of providing a substrate with interconnects. Stage 1 of FIG. 14A, illustrates and describes an example of providing a substrate with interconnects.

The method couples (at 1510) an integrated device (e.g., 104) to the substrate. For example, the integrated device 104 may be coupled to a first surface (e.g., top surface) of the substrate 102. The integrated device 104 is coupled to the substrate 102 through the plurality of solder interconnects 140. A solder reflow process may be used to couple the integrated device 104 to the substrate 102. Stage 2 of FIG. 13A, illustrates and describes an example of coupling an integrated device to a substrate. Stage 2 of FIG. 14A, illustrates and describes an example of coupling an integrated device to a substrate.

The method forms (at 1515) an encapsulation layer (e.g., 108) over the first surface of the substrate (e.g., 102, 302). The encapsulation layer 108 may be provided and formed over and/or around the substrate (e.g., 102, 302) and the integrated device 104. The encapsulation layer 108 may include a mold, a resin and/or an epoxy. A compression molding process, a transfer molding process, or a liquid molding process may be used to form the encapsulation layer 108. The encapsulation layer 108 may be photo etchable. The encapsulation layer 108 may be a means for encapsulation. Stage 3 of FIG. 13A, illustrates and describes an example of forming an encapsulation layer. Stage 3 of FIG. 14A, illustrates and describes an example of forming an encapsulation layer.

The method forms (at 1520) a metal layer (e.g., 109) over a surface of the encapsulation layer 108 and a side surface of the substrate (e.g., 102, 302). The metal layer 109 may be configured as an electromagnetic interference (EMI) shield. The metal layer 109 may be configured to be coupled to ground. The metal layer 109 may be coupled to an interconnect of the substrate (e.g., 102, 302). A sputtering process may be used to form the metal layer. Stage 4 of FIG. 13B, illustrates and describes an example of forming a metal layer. Stage 4 of FIG. 14B, illustrates and describes an example of forming a metal layer.

The method couples (at 1525) a plurality of solder interconnects (e.g., 130) to the substrate (e.g., 102, 302). A solder reflow process may be used to couple the plurality of solder interconnects 130 to the substrate. Stage 4 of FIG. 13B, illustrates and describes an example of coupling solder interconnects to a substrate. Stage 4 of FIG. 14B, illustrates and describes an example of coupling solder interconnects to a substrate.

The packages (e.g., 100, 300) described in the disclosure may be fabricated one at a time or may be fabricated together as part of one or more wafers and then singulated into individual packages.

### Exemplary Electronic Devices

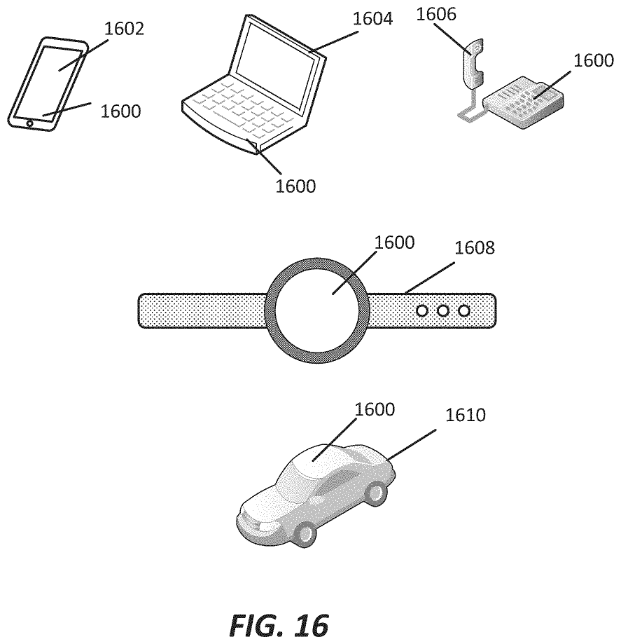

FIG. 16 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1602, a laptop computer device 1604, a fixed location terminal device 1606, a wearable device 1608, or automotive vehicle 1610 may include a device 1600 as described herein. The device 1600 may be, for example, any of the devices and/or integrated circuit (IC) packages described herein. The devices 1602, 1604, 1606 and 1608 and the vehicle 1610 illustrated in FIG. 16 are merely exemplary. Other electronic devices may also feature the device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-8, 9A-9D, 10, 11A-11E, 12, 13A-13B, 14A-14B and/or 15-16 may be rearranged and/or combined into a single component, process, feature or function or embodied in several components, processes, or functions. Additional elements, components, processes, and/or functions may also be added without departing from the disclosure. It should also be noted FIGS. 1-8, 9A-9D, 10, 11A-11E, 12, 13A-13B, 14A-14B and/or 15-16 and its corresponding description in the present disclosure is not limited to dies and/or ICs. In some implementations, FIGS. 1-8, 9A-9D, 10, 11A-11E, 12, 13A-13B, 14A-14B and/or 15-16 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. There may or may not be one or more interfaces between interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects. The process of forming one or more interconnects may include desmearing, masking, mask removal, and/or etching.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a substrate and an integrated device coupled to the substrate. The substrate includes at least one dielectric layer and a plurality of interconnects comprising a first pad interconnect. The first pad interconnect includes a first portion comprising a first width and a second portion comprising a second width that is different than the first width.

Aspect 2: The package of aspect 1, wherein the second portion comprises a circular planar cross-section.

Aspect 3: The package of aspect 1, wherein the second portion comprises a non-circular planar cross-section.

Aspect 4: The package of aspect 1, wherein the second portion comprises a cross planar cross-section.

Aspect 5: The package of aspect 1, wherein the second portion comprises a planar cross-section that has a shape of a circle and a cross that have been combined.

Aspect 6: The package of aspects 1 through 5, wherein the first pad interconnect is located over a second surface of the substrate.

Aspect 7: The package of aspects 1 through 5, wherein the first pad interconnect is located over a first surface of the substrate.

Aspect 8: The package of aspects 1 through 7, wherein the integrated device is coupled to the substrate through the first pad interconnect.

Aspect 9: The package of aspects 1 through 8, further comprising a solder resist layer located over a first surface of the at least one dielectric layer, wherein the solder resist layer has a thickness that is equal or greater than the thickness of the first pad interconnect.

Aspect 10: The package of aspects 1 through 8, further comprising a solder resist layer located over part of the first portion of the first pad interconnect.

Aspect 11: The package of aspect 10, wherein the solder resist layer has a thickness that is equal or greater than the thickness of the first portion of the first pad interconnect.

Aspect 12: The package of aspects 1 through 11, wherein the integrated device is coupled to the first pad interconnect of the substrate through a solder interconnect, and wherein the solder interconnect is coupled to the first portion and/or the second portion of the first pad interconnect of the substrate.

Aspect 13: The package of aspects 1 through 11, further comprising a solder interconnect coupled to the first portion and/or the second portion of the first pad interconnect of the substrate.

Aspect 14: The package of aspects 1 through 13, wherein the substrate includes a core layer.

Aspect 15: An apparatus includes a substrate. The substrate includes at least one dielectric layer and a plurality of interconnects comprising a first pad interconnect. The first pad interconnect comprises a first portion comprising a first width and a second portion comprising a second width that is different than the first width.

Aspect 16: The apparatus of aspect 15, wherein the second portion comprises a circular planar cross-section.

Aspect 17: The apparatus of aspect 15, wherein the second portion comprises a non-circular planar cross-section.

Aspect 18: The apparatus of aspects 15 through 17, wherein the first pad interconnect is located over a second surface of the substrate.

Aspect 19: The apparatus of aspects 15 through 17, wherein the first pad interconnect is located over a first surface of the substrate.

Aspect 20: The apparatus of aspects 15 through 19, further comprising a solder resist layer located over a first surface of the at least one dielectric layer, wherein the solder resist layer has a thickness that is equal or greater than the thickness of the first pad interconnect.

Aspect 21: The apparatus of aspects 15 through 19, further comprising a solder resist layer located over part of the first portion of the first pad interconnect.

Aspect 22: The apparatus of aspects 15 through 21, further comprising a solder interconnect coupled to the first portion and/or the second portion of the first pad interconnect of the substrate.

Aspect 23: The apparatus of aspects 15 through 22, wherein the substrate includes a core layer.

Aspect 24: The apparatus of aspects 15 through 23, wherein the apparatus includes a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 25: A method for fabricating a substrate. The method provides at least one dielectric layer. The method forms a plurality of interconnects comprising a first pad interconnect. The first pad interconnect comprises a first portion comprising a first width and a second portion comprising a second width that is different than the first width.

Aspect 26: The method of aspect 25, wherein the second portion comprises a circular planar cross-section.

Aspect 27: The method of aspect 25, wherein the second portion comprises a non-circular planar cross-section.

Aspect 28: The method of aspects 25 through 27, wherein the first pad interconnect is located over a second surface of the substrate.

Aspect 29: The method of aspects 25 through 27, wherein the first pad interconnect is located over a first surface of the substrate.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising:
at least one dielectric layer; and
a plurality of interconnects comprising a first pad interconnect, wherein the first pad interconnect comprises:
a first portion comprising a first width; and
a second portion comprising a second width that is different than the first width; and
an integrated device coupled to the substrate.

2. The package of claim 1, wherein the second portion comprises a circular planar cross-section.

3. The package of claim 1, wherein the second portion comprises a non-circular planar cross-section.

4. The package of claim 1, wherein the second portion comprises a cross planar cross-section.

5. The package of claim 1, wherein the second portion comprises a planar cross-section that has a shape of a circle and a cross that have been combined.

6. The package of claim 1, wherein the first pad interconnect is located over a second surface of the substrate.

7. The package of claim 1, wherein the first pad interconnect is located over a first surface of the substrate.

8. The package of claim 1, wherein the integrated device is coupled to the substrate through the first pad interconnect.

9. The package of claim 1, further comprising a solder resist layer located over a first surface of the at least one dielectric layer, wherein the solder resist layer has a thickness that is equal or greater than the thickness of the first pad interconnect.

10. The package of claim 1, further comprising a solder resist layer located over part of the first portion of the first pad interconnect.

11. The package of claim 10, wherein the solder resist layer has a thickness that is equal or greater than the thickness of the first portion of the first pad interconnect.

12. The package of claim 1,
wherein the integrated device is coupled to the first pad interconnect of the substrate through a solder interconnect, and
wherein the solder interconnect is coupled to the first portion and/or the second portion of the first pad interconnect of the substrate.

13. The package of claim 1, further comprising a solder interconnect coupled to the first portion and/or the second portion of the first pad interconnect of the substrate.

14. The package of claim 1, wherein the substrate includes a core layer.

15. An apparatus comprising:
a substrate comprising:
at least one dielectric layer; and
a plurality of interconnects comprising a first pad interconnect, wherein the first pad interconnect comprises:
a first portion comprising a first width; and
a second portion comprising a second width that is different than the first width.

16. The apparatus of claim 15, wherein the second portion comprises a circular planar cross-section.

17. The apparatus of claim 15, wherein the second portion comprises a non-circular planar cross-section.

18. The apparatus of claim 15, wherein the first pad interconnect is located over a second surface of the substrate.

19. The apparatus of claim 15, wherein the first pad interconnect is located over a first surface of the substrate.

20. The apparatus of claim 15, further comprising a solder resist layer located over a first surface of the at least one dielectric layer, wherein the solder resist layer has a thickness that is equal or greater than the thickness of the first pad interconnect.

21. The apparatus of claim 15, further comprising a solder resist layer located over part of the first portion of the first pad interconnect.

22. The apparatus of claim 15, further comprising a solder interconnect coupled to the first portion and/or the second portion of the first pad interconnect of the substrate.

23. The apparatus of claim 15, wherein the substrate includes a core layer.

24. The apparatus of claim 15, wherein the apparatus includes a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

25. A method for fabricating a substrate, comprising:
providing at least one dielectric layer; and
forming a plurality of interconnects comprising a first pad interconnect, wherein the first pad interconnect comprises:
a first portion comprising a first width; and
a second portion comprising a second width that is different than the first width.

26. The method of claim 25, wherein the second portion comprises a circular planar cross-section.

27. The method of claim 25, wherein the second portion comprises a non-circular planar cross-section.

28. The method of claim 25, wherein the first pad interconnect is located over a second surface of the substrate.

29. The method of claim 25, wherein the first pad interconnect is located over a first surface of the substrate.
